(19) United States
(12) Patent Application Publication
(10) Pub. No.: US 2012/0007151 A1
(43) Pub. Date: Jan. 12, 2012

(54) SEMICONDUCTOR INTEGRATED CIRCUIT DEVICE AND MANUFACTURING METHOD OF SEMICONDUCTOR INTEGRATED CIRCUIT DEVICE

(75) Inventors: Hiromasa YOSHIMORI, Kanagawa (JP); Toshiaki Iwamatsu, Kanagawa (JP)

(73) Assignee: RENESAS ELECTRONICS CORPORATION

(21) Appl. No.: 13/166,289

(22) Filed: Jun. 22, 2011

(30) Foreign Application Priority Data
Jul. 6, 2010 (JP) 2010-153972

(51) Int. Cl. H01L 27/092; H01L 21/302; H01L 29/78

(52) U.S. Cl. 257/255; 257/329; 438/444; 257/E27.062; 257/E29.262; 257/E21.214

(57) ABSTRACT

A high breakdown voltage circuit containing a high breakdown voltage MOSFET in LSI, unlike a quintessential internal circuit, has an operating voltage fixed in a high state due to the relation with the outside and, therefore, miniaturization by the voltage lowering can not be applied, differing from ordinary cases. Consequently, the voltage lowering of an internal circuit part results in a furthermore enlargement of occupying area in the chip. The present inventors evaluated various measures for the problem, and made it clear that such problems as compatibility with the CMOSFET circuit configuration and device configuration, etc. constitute obstacles.

The present invention is a semiconductor integrated circuit device having MISFETs of an N-channel type and a P-channel type, each provided with a wave undulation on a channel surface, wherein the wave undulation provided on the channel surface of the N-channel type MISFET has a narrower pitch than that of the wave undulation provided on the channel surface of the P-channel type MISFET.

### CROSS-REFERENCE TO RELATED APPLICATION

The disclosure of Japanese Patent Application No. 2010-153972 filed on Jul. 6, 2010 including the specification, drawings and abstract is incorporated herein by reference in its entirety.

### BACKGROUND

The present invention relates to a semiconductor integrated circuit device containing a low breakdown voltage part and a high breakdown voltage part, and to a technology that is effective when applied to high integration & high breakdown voltage technologies in a manufacturing method of a semiconductor integrated circuit device (or a semiconductor device).

Japanese Patent Laid-Open Nos. 1994-224424 (Patent Document 1) and 1993-291573 (Patent Document 2) disclose an N-channel type high breakdown voltage MOSFET into which a recess channel was introduced and for which a LOCOS (Local Oxidation of Silicon) process is employed for improving a punch-through breakdown voltage.

Japanese Patent Laid-Open No. 1990-90567 (Patent Document 3) discloses a longitudinal type MOSFET of a fine high breakdown voltage in which the channel is formed in a longitudinal direction, for improving the punch-through breakdown voltage.

Japanese Patent Laid-Open No. 1994-151453 (Patent Document 4) discloses a high breakdown voltage MOSFET provided with offset electric field relaxing regions on both sides of a rising channel region.

Japanese Patent Laid-Open No. 1995-131009 (Patent Document 5) discloses a MOSFET provided with plural trenches running on the surface of the channel region in the longitudinal direction or lateral direction, or with plural local trenches in concentric square shapes on the surface of the inner region, for securing an effective channel length or an effective channel width.

Yuanzheng Zhu, other 4 members, “Folded Gate LDMOS Transistor with Low On-resistance and High Transconductance,” IEEE Transaction on Electron Devices, vol. 48, No. 12, December 2001, pp 2917-2928 (Non-Patent Document 1) discloses a power device capable of obtaining a low On-Resistance and a high Transconductance by introducing a folded gate structure, as an N-channel type LDMOSFET (Laterally diffused MOSFET) to be built in a power IC.

### SUMMARY

As a control component for batteries and power sources, there is widely used LSI (Large Scale Integration) of a circuit configuration of a CMOSFET (Complementary metal oxide semiconductor Field Effect Transistor) or a CMISFET (Complementary metal insulator semiconductor Field Effect Transistor) in which a high breakdown voltage MOSFET is built, that is, a high breakdown voltage CMOSFET (CMISFET) integrated circuit device. Unlike a quintessential internal circuit, however, these high breakdown voltage MOSFETs (MISFETs) have an operating voltage fixed in a high state due to the relation with the outside and, therefore, miniaturization by the voltage lowering can not be applied, differing from ordinary cases. Consequently, the voltage lowering of an internal circuit part results in a furthermore enlargement of occupying area in the chip. The present inventors evaluated various measures for the problem, and made it clear that such problems as compatibility with the CMOSFET (CMISFET) circuit configuration and device configuration, etc. constitute obstacles.

The present invention was achieved to solve these problems.

The present invention has been made in view of the above circumstances and provides a semiconductor integrated circuit device having a high breakdown voltage and high integration.

The other purposes and the new feature of the present invention will become clear from the description of the present specification and the accompanying drawings.

The following explains briefly the outline of a typical invention among the inventions disclosed in the present application.

That is, one invention of the present application is a semiconductor integrated circuit device having MISFETs of an N-channel type and a P-channel type each provided with a wave undulation on a channel surface, wherein the wave undulation provided on the channel surface of the N-channel type MISFET has a narrower pitch than that of the wave undulation provided on the channel surface of the P-channel type MISFET.

The following explains briefly the effect acquired by the typical invention among the inventions disclosed in the present application.

That is, in a semiconductor integrated circuit device having MISFETs of an N-channel type and a P-channel type each provided with a wave undulation on a channel surface, the wave undulation provided on the channel surface of the N-channel type MISFET is set to have a narrower pitch than that of the wave undulation provided on the channel surface of the P-channel type MISFET. This enables minimization of the area occupied by the element.

### BRIEF DESCRIPTION OF THE DRAWINGS

FIG. 1 is a top face layout view of a CMOS integrated circuit chip that is an example of the object device of semiconductor integrated circuit devices according to respective embodiments of the present application;

FIG. 2 is a device cross-sectional view for explaining the outline of the semiconductor integrated circuit device and wafer process flow in the manufacturing method of the same according to respective embodiments of the present application (process of inputting a wafer);

FIG. 3 is a device cross-sectional view for explaining the outline of the semiconductor integrated circuit device and wafer process flow in the manufacturing method of the same according to respective embodiments of the present application (process of forming a LOCOS insulating film);

FIG. 4 is a device cross-sectional view for explaining the outline of the semiconductor integrated circuit device and wafer process flow in the manufacturing method of the same according to respective embodiments of the present application (process of introducing an N-well);

FIG. 5 is a device cross-sectional view for explaining the outline of the semiconductor integrated circuit device and wafer process flow in the manufacturing method of the same according to respective embodiments of the present application (process of introducing a P-well);

FIG. 6 is a device cross-sectional view for explaining the outline of the semiconductor integrated circuit device and wafer process flow in the manufacturing method of the same according to respective embodiments of the present application (process of forming a gate electrode);

FIG. 7 is a device cross-sectional view for explaining the outline of the semiconductor integrated circuit device and wafer process flow in the manufacturing method of the same according to respective embodiments of the present application (process of introducing a low concentration source drain region of an N-channel type low breakdown voltage MISFET);

FIG. 8 is a device cross-sectional view for explaining the outline of the semiconductor integrated circuit device and wafer process flow in the manufacturing method of the same according to respective embodiments of the present application (process of introducing a low concentration source drain region of an N-channel type high breakdown voltage MISFET);

FIG. 9 is a device cross-sectional view for explaining the outline of the semiconductor integrated circuit device and wafer process flow in the manufacturing method of the same according to respective embodiments of the present application (process of coating a resist film for introducing a low concentration source drain region of a P-channel type high breakdown voltage MISFET);

FIG. 10 is a device cross-sectional view for explaining the outline of the semiconductor integrated circuit device and wafer process flow in the manufacturing method of the same according to respective embodiments of the present application (process of introducing a low concentration source drain region of a P-channel type high breakdown voltage MISFET);

FIG. 11 is a device cross-sectional view for explaining the outline of the semiconductor integrated circuit device and wafer process flow in the manufacturing method of the same according to respective embodiments of the present application (process of forming a side wall);

FIG. 12 is a device cross-sectional view for explaining the outline of the semiconductor integrated circuit device and wafer process flow in the manufacturing method of the same according to respective embodiments of the present application (process of introducing a high concentration source drain region of an N-channel type MISFET);

FIG. 13 is a device cross-sectional view for explaining the outline of the semiconductor integrated circuit device and wafer process flow in the manufacturing method of the same according to respective embodiments of the present application (process of introducing a high concentration source drain region of a P-channel type MISFET);

FIG. 14 a device cross-sectional view for explaining the outline of the semiconductor integrated circuit device and wafer process flow in the manufacturing method of the same according to respective embodiments of the present application (process of forming a pre metal insulating film and forming wiring);

FIG. 15 is a local top face view of a semiconductor substrate showing the basic structure of the device common to the semiconductor integrated circuit devices of respective embodiments of the present application;

FIG. 16 is a local cross-sectional view of the device corresponding to the A-A′ cross-section in FIG. 15;

FIG. 17 is a local cross-sectional view of the device corresponding to the B-B′ cross-section in FIG. 15;

FIG. 18 is a local top face view of a semiconductor substrate showing the device structure of CMOS configuration in the semiconductor integrated circuit device of a first embodiment of the present application;

FIG. 19 is a local cross-sectional view of a device explaining a relevant part process flow in the C-C′ cross-section in FIG. 18 (process of forming various types of trenches before LOCOS oxidation);

FIG. 20 is a local cross-sectional view of a device explaining a relevant part process flow in the C-C′ cross-section in FIG. 18 (process of LOCOS oxidation and post-treatment);

FIG. 21 is a local cross-sectional view of a device explaining a relevant part process flow in the C-C′ cross-section in FIG. 18 (removal of an oxide film in the trench for ripple);

FIG. 22 is a local cross-sectional view of a device explaining a relevant part process flow in the C-C′ cross-section in FIG. 18 (process of oxidizing a gate and forming a gate polysilicon film);

FIG. 23 is a local cross-sectional view of a device explaining a relevant part process flow in the C-C′ cross-section in FIG. 18 (process of flattening the upper face of the gate polysilicon film);

FIG. 24 is a local cross-sectional view of a device explaining a relevant part process flow in the D-D′ cross-section in FIG. 18 (process of forming various types of trenches before LOCOS oxidation);

FIG. 25 is a local cross-sectional view of a device explaining a relevant part process flow in the D-D′ cross-section in FIG. 18 (removal of an oxide film in a trench for recess);

FIG. 26 is a local cross-sectional view of a device explaining a relevant part process flow in the D-D′ cross-section in FIG. 18 (process for flattening the upper face of the gate polysilicon film);

FIG. 27 is a local cross-sectional view of a device explaining a relevant part process flow in the D-D′ cross-section in FIG. 18 (process of patterning the gate polysilicon film);

FIG. 28 is a local cross-sectional view of a device explaining a relevant part process flow in the E-E′ cross-section in FIG. 18 (process of LOCOS oxidation);

FIG. 29 is a local cross-sectional view of a device explaining a relevant part process flow in the F-F′ cross-section in FIG. 18 (process of LOCOS oxidation);

FIG. 30 is a perspective view of the periphery of the gate electrode for explaining a side wall process common to semiconductor integrated circuit devices of respective embodiments of the present application (before the formation of the side wall);

FIG. 31 is a cross-sectional view of the periphery of the gate electrode corresponding to cross-sections 1 to 3 in FIG. 30 (before the formation of the side wall);

FIG. 32 is a cross-sectional view of the periphery of the gate electrode corresponding to cross-sections 1 to 3 in FIG. 30 (process of forming the side wall film);

FIG. 33 is a cross-sectional view of the periphery of the gate electrode corresponding to cross-sections 1 to 3 in FIG. 30 (process of dry-etching the upper layer film of the side wall film);

FIG. 34 is a cross-sectional view of the periphery of the gate electrode corresponding to cross-sections 1 to 3 in FIG. 30 (process of dry-etching the intermediate film of the side wall film);

FIG. 35 is a cross-sectional view of the periphery of the gate electrode corresponding to cross-sections 1 to 3 in FIG. 30 (time point of completing the dry etching process of the lower layer film of the side wall film);

FIG. 36 is a perspective view of the periphery of the gate electrode for explaining the side wall process common to semiconductor integrated circuit devices of respective embodiments of the present application (time point of completing the dry etching process of the lower layer film of the side wall film);

FIG. 37 is a local top face view of a semiconductor substrate showing the device structure of CMOS configuration in the semiconductor integrated circuit device of a second embodiment of the present application;

FIG. 38 is a local cross-sectional view of a device explaining a relevant part process flow in the C-C′ cross-section in FIG. 37 (process for forming a trench for an n-channel side ripple);

FIG. 39 is a local cross-sectional view of a device explaining a relevant part process flow in the C-C′ cross-section in FIG. 37 (process for forming a trench for a p-channel side ripple);

FIG. 40 is a local cross-sectional view of a device explaining a relevant part process flow in the C-C′ cross-section in FIG. 37 (process of flattening the upper face of the gate polysilicon film);

FIG. 41 is a local cross-sectional view of a device explaining a relevant part process flow in the D-D′ cross-section in FIG. 37 (process of forming the trench for the ripple on an n-channel side before the LOCOS oxidation);

FIG. 42 is a local cross-sectional view of a device explaining a relevant part process flow in the D-D′ cross-section in FIG. 37 (process of forming a trench in a recess channel part and a recess drain part before the LOCOS oxidation);

FIG. 43 is a schematic view of the wafer top face explaining the alignment of the crystal plane orientation of a silicon single crystal and the channel direction (the channel length direction) of the high breakdown voltage MISFET common to semiconductor integrated circuit devices of respective embodiments of the present application (alignment example 1);

FIG. 44 is a schematic view of the wafer top face explaining the alignment of the crystal plane orientation of a silicon single crystal and the channel direction (the channel length direction) of the high breakdown voltage MISFET common to semiconductor integrated circuit devices of respective embodiments of the present application (alignment example 2);

FIG. 45 is a schematic view of the wafer top face explaining the alignment of the crystal plane orientation of a silicon single crystal and the channel direction (the channel length direction) of the high breakdown voltage MISFET common to the semiconductor integrated circuit devices of respective embodiments of the present application (alignment example 3);

FIG. 46 is a schematic view of the wafer top face explaining the alignment of the crystal plane orientation of a silicon single crystal and the channel direction (the channel length direction) of the high breakdown voltage MISFET common to the semiconductor integrated circuit devices of respective embodiments of the present application (alignment example 4);

FIG. 47 is a schematic view of the wafer top face explaining the alignment of the crystal plane orientation of a silicon single crystal and the channel direction (the channel length direction) of the high breakdown voltage MISFET common to the semiconductor integrated circuit devices of respective embodiments of the present application (alignment example 5);

FIG. 48 is a schematic view of the wafer top face explaining the alignment of the crystal plane orientation of a silicon single crystal and the channel direction (the channel length direction) of the high breakdown voltage MISFET common to the semiconductor integrated circuit devices of respective embodiments of the present application (alignment example 6);

FIG. 49 is an explanatory view showing a trench cross-section for showing the degree of easiness of the appearance of (110) plane in the case of the alignment in FIG. 43;

FIG. 50 is an explanatory view showing a trench cross-section for showing the degree of easiness of the appearance of (110) plane in the case of the alignment in FIG. 44; and

FIG. 51 is a cross-sectional view of a device of parts corresponding to the ripple trench, various types of recess trenches, the element isolation trench, etc. formed in FIGS. 19, 24, 39 and 41, etc. for explaining the recession treatment of the insulating film for LOCOS oxidation.

### DETAILED DESCRIPTION

### Outline of Embodiment

Firstly, the following is the outline of typical embodiments of the invention disclosed in the present application.

1. A semiconductor integrated circuit device, comprising: (a) a semiconductor substrate having a first and a second main surface; (b) a first N-channel type MISFET and a first P-channel type MISFET provided over the first main surface of the semiconductor substrate; (c) a first wave undulation provided over the surface of a first channel region of the first N-channel type MISFET so as to lie along the channel width direction; and (d) a second wave undulation provided over the surface of a second channel region of the first P-channel type MISFET so as to lie along the channel width direction, wherein the pitch of the first wave undulation is shorter than that of the second wave undulation.

2. The semiconductor integrated circuit device according to item 1, wherein the first wave undulation is provided extending from a first source region to a first drain region of the first N-channel type MISFET, and the second wave undulation is provided extending from a second source region to a second drain region of the first P-channel type MISFET.

3. The semiconductor integrated circuit device according to item 2, wherein the first wave undulation is provided extending between respective contact regions of the first source region and the first drain region of the first N-channel type MISFET, and the second wave undulation is provided extending between respective contact regions of the second source region and the second drain region of the first P-channel type MISFET.

4. The semiconductor integrated circuit device according to item 3, wherein the respective contacts of the respective contact regions are provided for both top and bottom parts of the respective first wave undulation and the second wave undulation.

5. The semiconductor integrated circuit device according to any one of items 1 to 4, wherein a first in-channel recess region is provided in the surface in an approximately central part of the first channel region so as to lie along the channel width direction, and a second in-channel recess region is provided in the surface in an approximately central part of the second channel region so as to lie along the channel width direction.

6. The semiconductor integrated circuit device according to any one of items 1 to 5, further comprising: (e) a second N-channel type MISFET and a second P-channel type MISFET provided over the first main surface of the semiconductor substrate, wherein the source-drain breakdown voltage of the first N-channel type MISFET is higher than that of the second N-channel type MISFET, and the source-drain breakdown voltage of the first P-channel type MISFET is higher than that of the second P-channel type MISFET.

7. The semiconductor integrated circuit device according to any one of items 1 to 6, wherein the first drain region includes: (x1) a low concentration N-type drain region; (x2) a high concentration N-type drain region that is provided in a surface region in the low concentration N-type drain region and has a higher impurity concentration than the low concentration N-type drain region; and (x3) a recess region in the N-type drain provided in the surface of the low concentration N-type drain region without the high concentration N-type drain region so as to lie along the channel width direction, and, furthermore, the second drain region includes: (y1) a low concentration P-type drain region; (y2) a high concentration P-type drain region that is provided in a surface region in the low concentration P-type drain region and has a higher impurity concentration than the low concentration P-type drain region; and (y3) a recess region in the P-type drain provided in the surface of the low concentration P-type drain region without the high concentration P-type drain region so as to lie along the channel width direction.

8. The semiconductor integrated circuit device according to any one of items 1 to 7, wherein the wave height of the second wave undulation and that of the first wave undulation are approximately equal to each other.

9. The semiconductor integrated circuit device according to any one of items 1 to 8, wherein the semiconductor chip is a silicon-based semiconductor, the first main surface has a crystal plane of approximately (100) plane, and respective channel length directions of the first N-channel type MISFET and the first P-channel type MISFET lie approximately along the crystal orientation <100>.

10. The semiconductor integrated circuit device according to any one of items 1 to 8, wherein the semiconductor chip is a silicon-based semiconductor, the first main surface has a crystal plane of approximately (100) plane, and respective channel length directions of the first N-channel type MISFET and the first P-channel type MISFET lie approximately along the crystal orientation <110>.

11. A semiconductor integrated circuit device, comprising: (a) a semiconductor substrate having a first and a second main surface; (b) a first N-channel type MISFET and a first P-channel type MISFET provided over the first main surface of the semiconductor substrate; (c) a first wave undulation provided over the surface of a first channel region of the first N-channel type MISFET so as to lie along a channel width direction; and (d) a second wave undulation provided over the surface of a second channel region of the first P-channel type MISFET so as to lie along the channel width direction, wherein the wave height of the first wave undulation is higher than that of the second wave undulation.

12. The semiconductor integrated circuit device according to item 11, wherein the semiconductor chip is a silicon-based semiconductor, the first main surface has a crystal plane of approximately (100) plane, and respective channel length directions of the first N-channel type MISFET and the first P-channel type MISFET lie approximately along the crystal orientation <100>.

13. The semiconductor integrated circuit device according to item 11, wherein the semiconductor chip is a silicon-based semiconductor, the first main surface has a crystal plane of approximately (100) plane, and respective channel length directions of the first N-channel type MISFET and the first P-channel type MISFET lie approximately along the crystal orientation <110>.

14. A semiconductor integrated circuit device, comprising: (a) a semiconductor substrate having a first and a second main surface; (b) a first N-channel type MISFET and a first P-channel type MISFET that are provided over the first main surface of the semiconductor substrate in close vicinity to each other and constitute a first pair of CMISFETs; (c) a first wave undulation provided over the surface of a first channel region of the first N-channel type MISFET so as to lie along a channel width direction; and (d) a second wave undulation provided over the surface of a second channel region of the first P-channel type MISFET so as to lie along the channel width direction.

15. The semiconductor integrated circuit device according to item 14, further comprising: (e) a second N-channel type MISFET and a second P-channel type MISFET provided over the first main surface of the semiconductor substrate, wherein the source-drain breakdown voltages of the first N-channel type MISFET and the first P-channel type MISFET are higher than those of the second N-channel type MISFET and the second P-channel type MISFET.

16. A manufacturing method of a semiconductor integrated circuit device, the semiconductor integrated circuit device including: (a) a semiconductor substrate having a first and a second main surface; (b) a first N-channel type MISFET and a first P-channel type MISFET provided over the first main surface of the semiconductor substrate; (c) a first wave undulation provided over the surface of a first channel region of the first N-channel type MISFET so as to lie along a channel width direction; (d) a second wave undulation provided over the surface of a second channel region of the first P-channel type MISFET so as to lie along the channel width direction; (e) a first in-channel recess region provided in the surface in an approximately central part of the first channel region so as to lie along the channel width direction; and (f) a second in-channel recess region provided in the surface in an approximately central part of the second channel region so as to lie along the channel width direction, wherein the manufacturing method of a semiconductor integrated circuit device comprises the step of: (p1) forming the first wave undulation and the first in-channel recess region approximately at the same time.

17. The manufacturing method of a semiconductor integrated circuit device according to item 16, the semiconductor integrated circuit device including: (g) a LOCOS element isolation insulating film element-isolating the first N-channel type MISFET and the first P-channel type MISFET over the first main surface of the semiconductor substrate, wherein the manufacturing method of a semiconductor integrated circuit device further comprises the step of: (p2) after the step (p1), carrying out, approximately at the same time, oxidation for chamfering respective corner parts of the first wave undulation, the second wave undulation, the first in-channel recess region, and the second in-channel recess region, and oxidation for forming the LOCOS element isolation insulating film.

18. The manufacturing method of a semiconductor integrated circuit device according to item 16 or 17, wherein the pitch of the first wave undulation is shorter than that of the second wave undulation.

19. The manufacturing method of a semiconductor integrated circuit device according to any one of items 16 to 18, wherein the first wave undulation and the second wave undulation are formed by different processes.

20. The manufacturing method of a semiconductor integrated circuit device according to any on of items 17 to 19, further comprising the step of: (p3) after the step (p2), removing the oxide film formed in the oxidation for the chamfering in a state where the LOCOS element isolation insulating film is covered with an etching-resistant material.

### [Explanation of Description Forms, Basic Terms, and Usages in the Present Application]

1. In the present application, embodiments will be described, divided into plural sections, if necessary for convenience. Except for the case where it is clearly specified contrarily in particular, they are not mutually unrelated but are respective parts of a single example, one is a part of details or modified example of a part or entire of another, etc. Moreover, the repetition of same parts is omitted in general. Furthermore, respective constituent elements in embodiments are not indispensable, except for the case where it is clearly specified contrarily in particular, where it is theoretically restricted to the number, and where it is clearly considered to be not right from the context.

Furthermore, in the present application, a “semiconductor device” or a “semiconductor integrated circuit device” means mainly one formed by integrating single bodies of various transistors (active elements) and, around them as the center, a resist, a condenser etc. over a semiconductor chip etc. (for example, a single crystalline silicon substrate). Representative examples of the various kinds of transistors include MISFETs (Metal Insulator Semiconductor Field Effect Transistor) represented by a MOSFET (Metal Oxide Semiconductor Field Effect Transistor). On this occasion, representative examples of integrated circuit configurations include CMIS (Complementary Metal Insulator Semiconductor) type integrated circuits represented by a CMOS (Complementary Metal Oxide Semiconductor) type integrated circuit formed by combining an N-channel type MISFET and a P-channel type MISFET.

The wafer process of semiconductor integrated circuit devices now, that is, LSI (Large Scale Integration) is usually classified roughly into a FEOL (Front End of Line) process from the carry-in of a silicon wafer as a raw material to around a premetal process (process constituted of the formation of an interlayer insulating film etc. between the lower end of an M1 wiring layer and a gate electrode structure, the formation of a contact hole, the embedding of a tungsten plug, etc.), and a BEOL (Back End of Line) process that begins from the formation of an M1 wiring layer to around the formation of a pad opening in a final passivation film lying over an aluminum-based pad electrode (in a wafer level package process, the process is also included).

2. Similarly, in the description of embodiments etc., when materials, compositions etc. are referred to as “X constituted of A” etc., those containing an element other than A as one of major constituent elements are not excluded, except for the case where it is clearly specified contrarily in particular and where it is considered clearly to be not right from the context. For example, with regard to a component, it means “X containing A as a major component” etc. For example, needless to say, “a silicon material” etc. are not restricted to pure silicon, but include SiGe alloy and other multi-component alloys containing silicon as a major component, and other materials containing an impurity etc. Similarly, needless to say, “a silicon oxide film,” “a silicon oxide-based insulating film” etc. include not only a relatively pure undoped silicon dioxide, but also thermally-oxidized films such as FSG (Fluorosilicate Glass), TEOS-based silicon oxide, SiOC (Silicon Oxicarbide) or carbon-doped silicon oxide or OSG (Organosilicate glass), PSG (Phosphorus Silicate Glass) and BPSG

(Borophosphosilicate Glass), CVD oxidized films, coating-based silicon oxides such as SOG (Spin ON Glass) and Nano-Clustering Silica (NCS), silica-based Low-k insulating films (porous-based insulating films) formed by introducing holes into materials similar to these, and composite films containing these as a major constituent element with another silicon-based insulating film.

As a silicon-based insulating film commonly used in the semiconductor field in concurrence with a silicon oxide-based insulating film, there is a silicon nitride-based insulating film. Materials of the series include SiN, SiCN, SiNH, SiCNH, etc. Here, the expression of “silicon nitride” includes both SiN and SiNH, except for the case where it is clearly specified contrarily in particular. Similarly, the expression of “SiCN” includes both SiCN and SiCNH, except for the case where it is clearly specified contrarily in particular.

Meanwhile, SiC has nature similar to that of SiN, but frequently SiON is to be classified rather into a silicon oxide-based insulating film.

The silicon nitride film is used frequently as an etch stop film in a SAC (Self-Aligned Contact) technique, and is used, in addition, as a stress-providing film in a SMT (Stress Memorization Technique).

3. Similarly, needless to say, preferable examples are shown for figures, positions, properties, etc., but they are not strictly restricted to the examples, except for the case where it is clearly specified contrarily and the case where it is clearly considered to be not right from the context.

4. Furthermore, when a specified numeric value or amount is referred to, it may be a numeric value exceeding the specified numeric value or a numeric value less than the specified numeric value, except for the case where it is clearly specified contrarily in particular, the case where it is restricted theoretically to the number, and the case where it is clearly considered to be not right from the context.

5. The expression of a “wafer” denotes ordinarily a single crystalline silicon wafer over which a semiconductor integrated circuit device (a semiconductor device and an electronic device mean the same) is to be formed, but, needless to say, it includes composite wafers of an insulating substrate, a semiconductor layer etc. such as an epitaxial wafer, an SOI substrate, an LCD glass substrate.

6. In the present application, for example, the expression such as (100) for the crystal plane is intended to include crystal planes equivalent to it. Moreover, the expression such as <100> or <110> for the crystal orientation is intended to include crystal orientations equivalent to it.

### Details of Embodiments

Embodiments will be described in more detail. In respective drawings, the same or similar parts are shown by the same or similar reference numbers, and the explanation is not repeated as a principle

Moreover, in accompanied drawings, when it becomes complicated against the intention or the distinction is clear from a void, hatching is omitted even for a cross-section. In this context, when it is clear from explanation etc., a profile line of background may be omitted even for a closed hole in a plane. Furthermore, hatching may be given even to a non cross-section, in order to show clearly that it is not a void.

Meanwhile, as a preceding patent application describing the wave undulation structure of the channel region, the recess drain structure, etc., for example, there is Japanese Patent Application No. 2010-48755 (Japanese Application Date: Mar. 5, 2010).

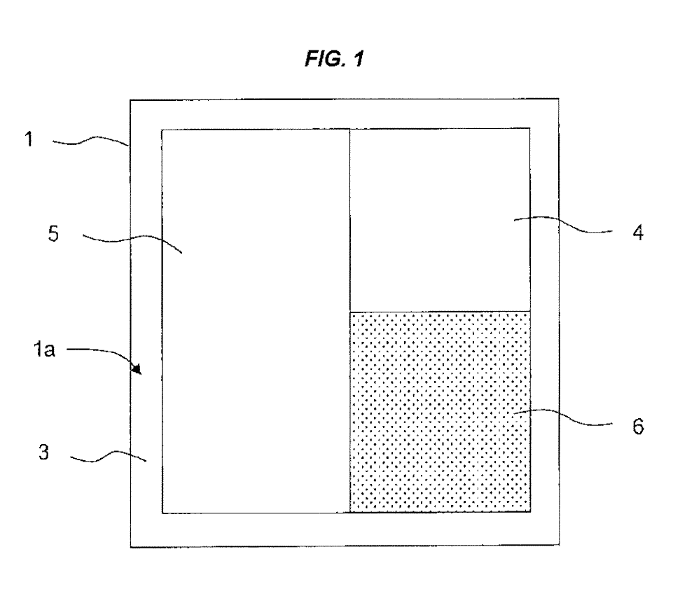

1. Explanation of a CMOS integrated circuit chip etc. that are an example of object device of the semiconductor integrated circuit device of respective embodiments of the present application (mainly FIG. 1)

Examples of specific applications of circuits explained below include integrated circuits using a power MOSFET etc. that control a high voltage of several tens of volts, that is, chips for controlling a battery, chips for controlling a power source, chips for controlling a motor, etc.

FIG. 1 is a top face layout view of a CMOS integrated circuit chip that is an example of the object device of semiconductor integrated circuit devices according to respective embodiments of the present application. On the basis of this, the following is the explanation of the configuration of the CMOS integrated circuit chip that is an example of object devices of semiconductor integrated circuit devices of respective embodiments of the present application.

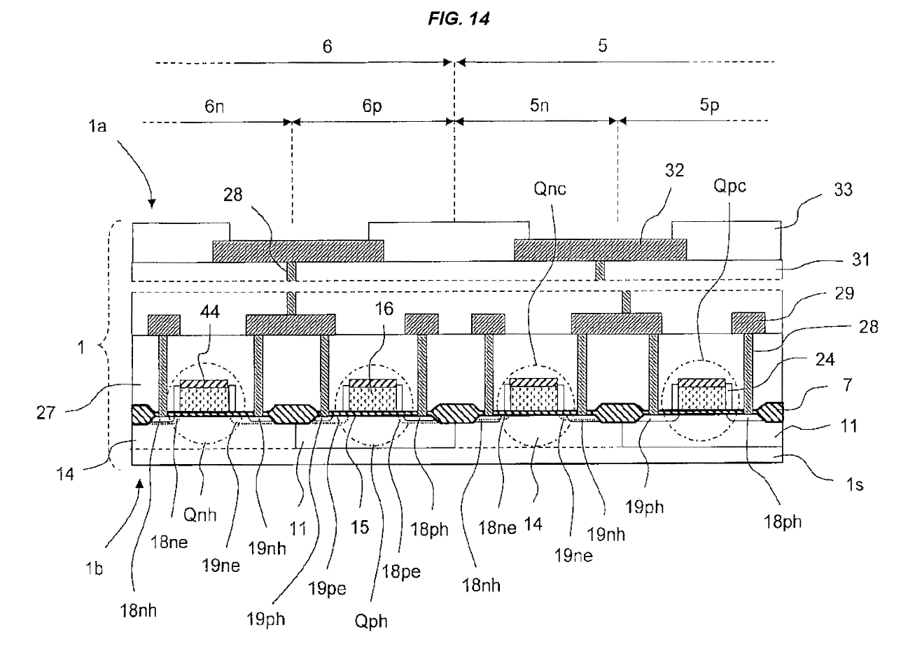

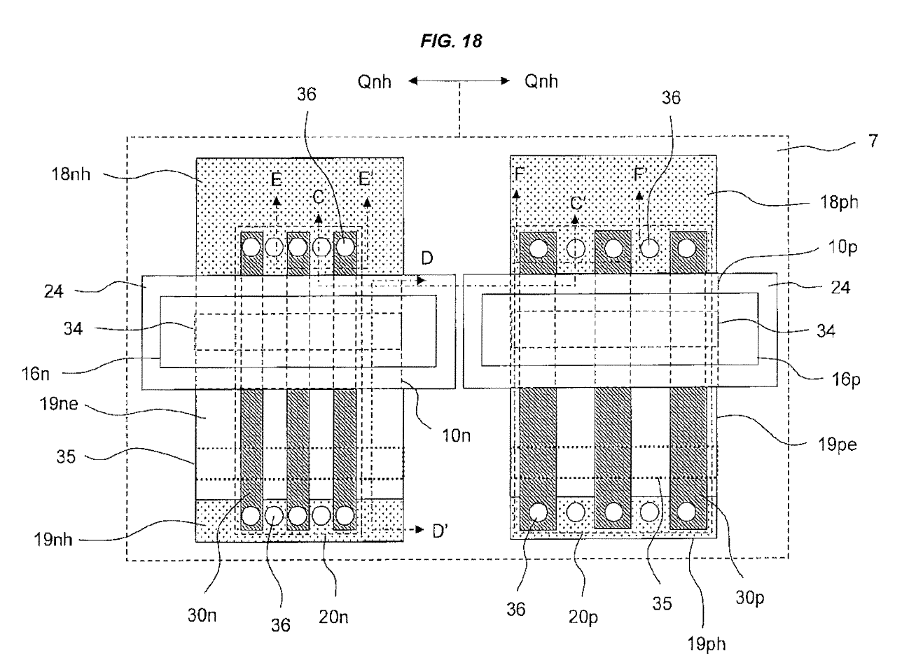

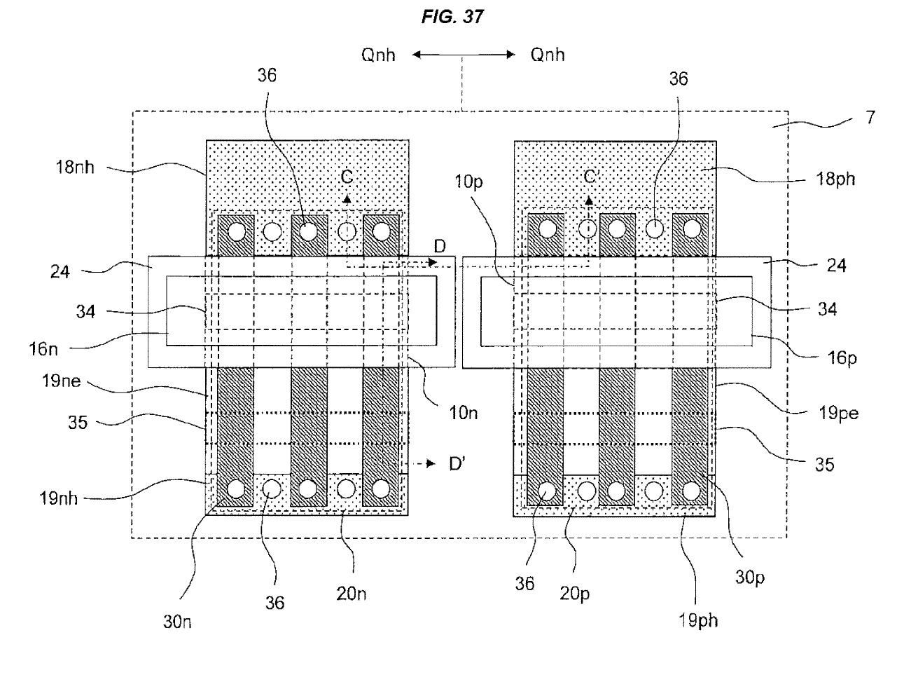

As shown in FIG. 1, a high breakdown voltage CMOS integrated circuit that is a substantial configuration in respective embodiments of the present application is provided in a high breakdown voltage circuit region 6 over a front side main surface 1a (the main surface lying on the opposite side of a back side main surface 1b) of a semiconductor chip 2, and, over the first main surface la of the chip 2, there are arranged, in addition for example, a low breakdown voltage logic circuit region 5, a memory circuit region 4, an I/O pad-disposing region 3 etc. The low breakdown voltage logic circuit region 5, the memory circuit region 4, the I/O pad-disposing region 3 etc. are mainly constituted of MISFETs (Qnc, Qpc) etc. having a comparatively low breakdown voltage (see FIG. 14), and the high breakdown voltage circuit region 6 (generally a part of the I/O pad-disposing region 3 has a high breakdown voltage MISFET) is constituted of MISFETs (Qnh, Qph) etc. having a comparatively high breakdown voltage (see FIGS. 14 and 18, or FIG. 37). Here, MISFETs (Qnc, Qpc) etc. having a comparatively low breakdown voltage and MISFETs (Qnh, Qph) etc. having a comparatively high breakdown voltage respectively constitute CMOS (CMIS) circuits (inverter, NAND circuit, NOR circuit, etc.).

Meanwhile, in the following explanation, the case will be specifically explained where MISFETs (Qnc, Qpc) of a low breakdown voltage have a standard gate length, for example, of around 0.3 μm, and MISFETs (Qnh, Qph) of a high breakdown voltage have a standard gate length, for example, of around 1 μm (lithography with the minimum dimension of around 0.3 μm is applied). But, needless to say, the gate length etc. of respective MISFETs may be selected in the range of around from several μm to 10 nm depending on a lithographic process to be used.

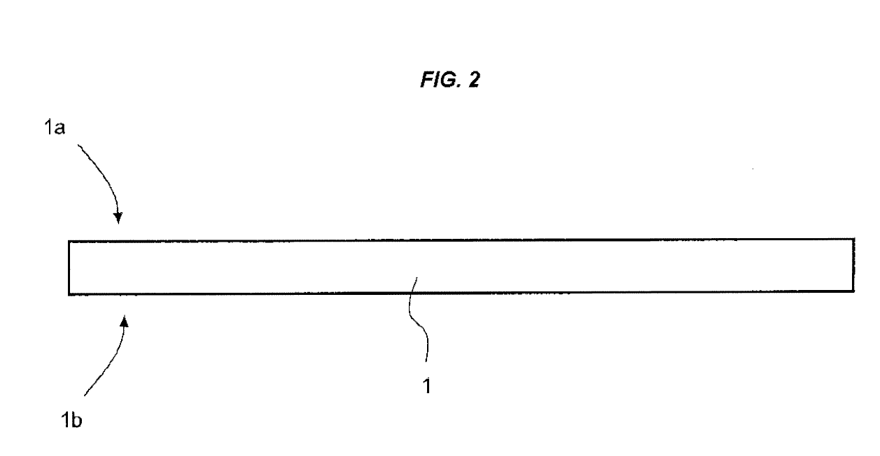

2. Explanation of the outline of the semiconductor integrated circuit device and wafer process flow in the manufacturing method of the same according to respective embodiments of the present application (mainly FIGS. 2 to 14)

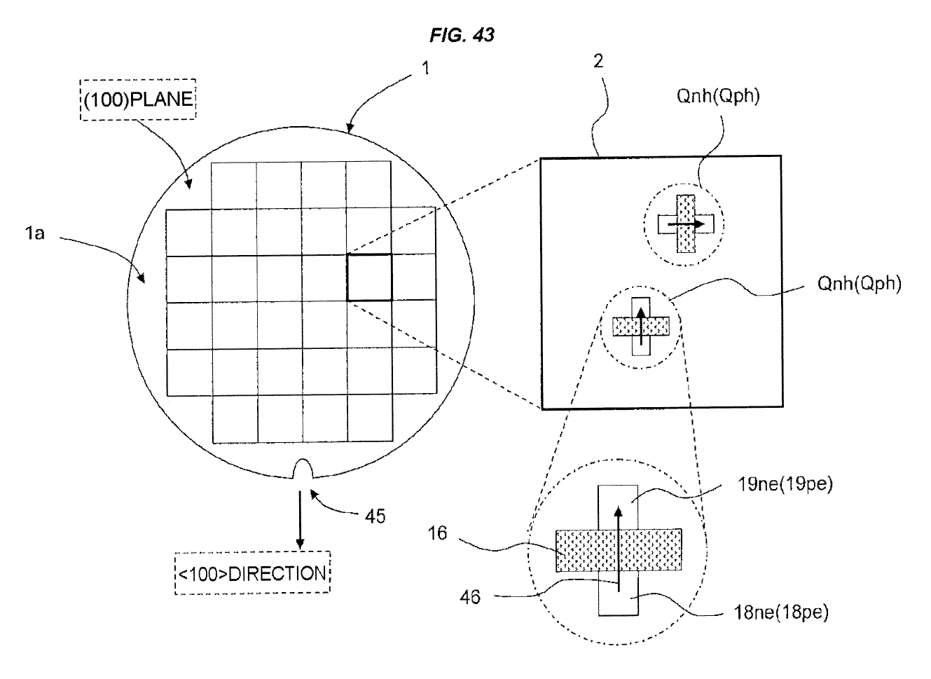

In this section, explanations will be given about the outline of wafer process of MISFETs (Qnc, Qpc) of a comparatively low breakdown voltage etc. used in the low breakdown voltage logic circuit region 5, the memory circuit region 4, the I/O pad-disposing region 3 etc. and MISFETs (Qnh, Qph) of a comparatively high breakdown voltage etc. used in the high breakdown voltage circuit region 6 having been explained in section 1. The crystal orientation of a wafer and the alignment (layout) of a device used here will be explained on condition of one in FIG. 43 (in particular, one having the alignment basically lying along the main axis of the chip for both channels of the MISFET of a high breakdown voltage and the MISFET of a low breakdown voltage), but, needless to say, another one is usable.

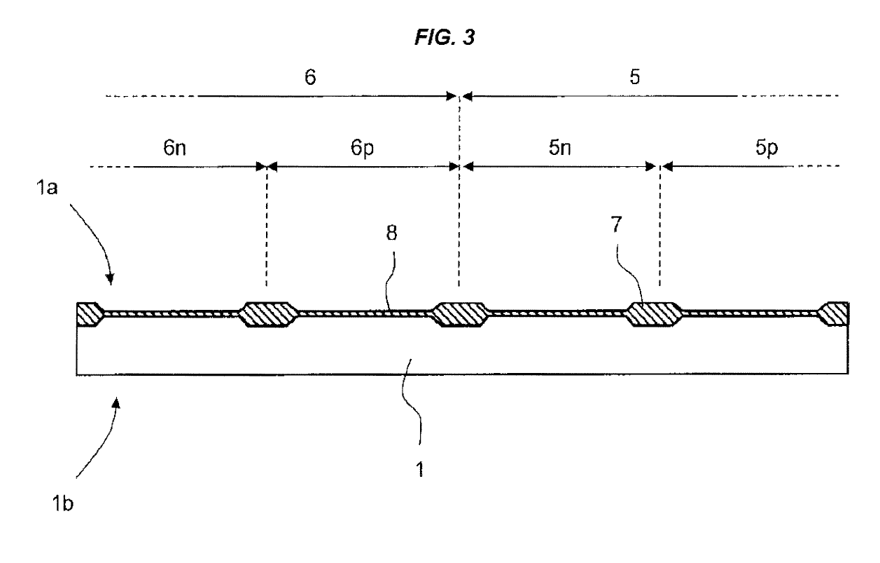

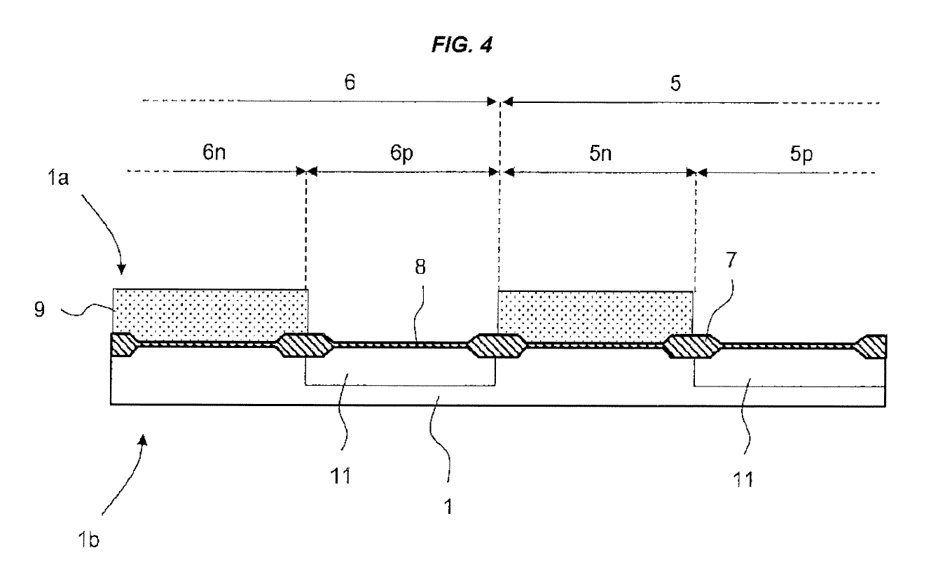

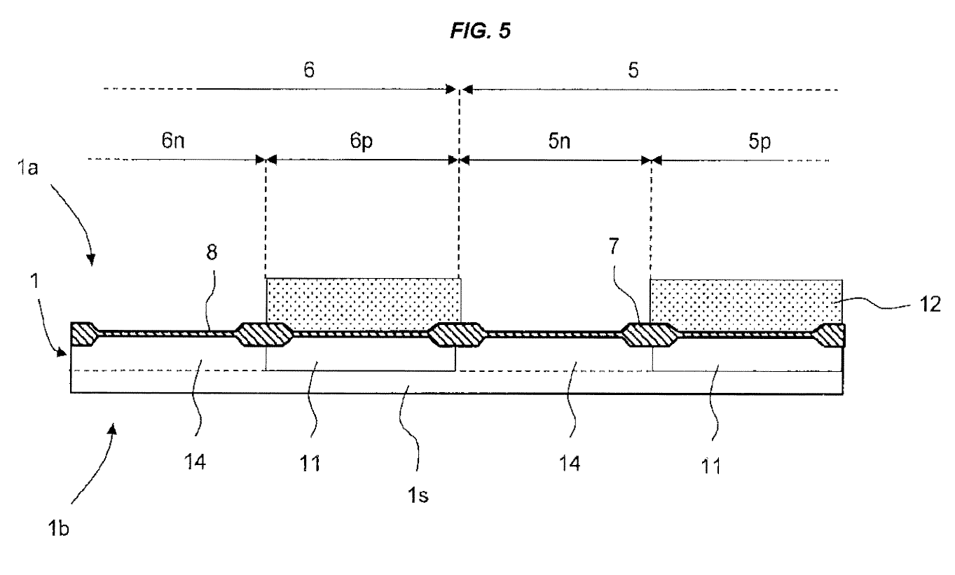

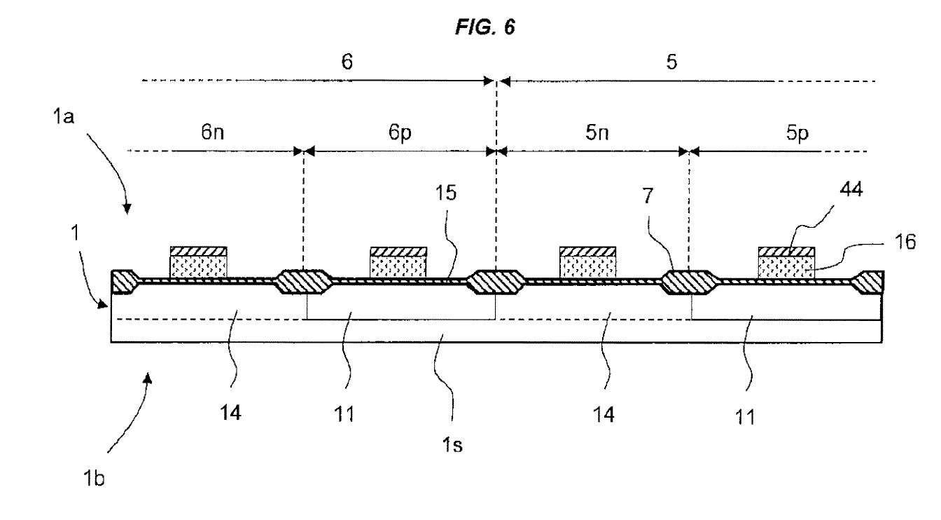

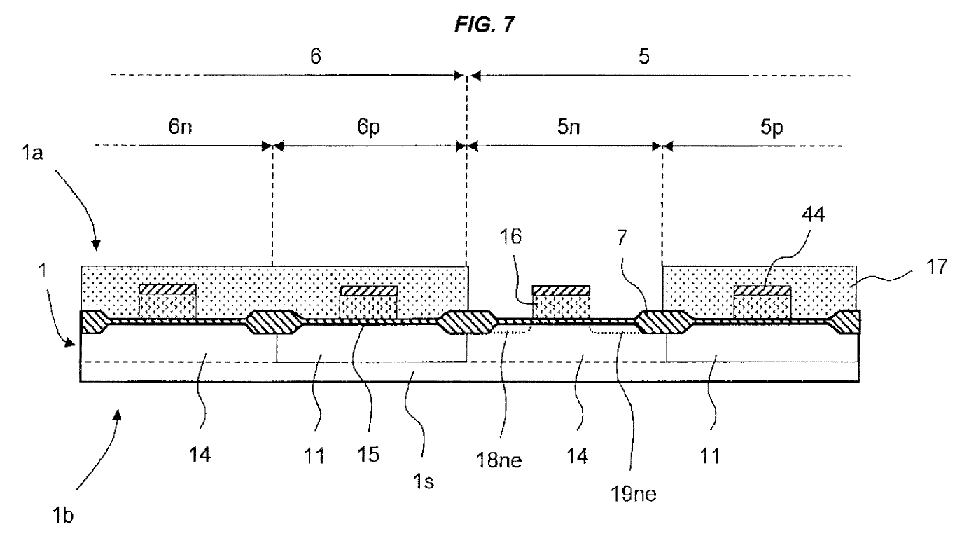

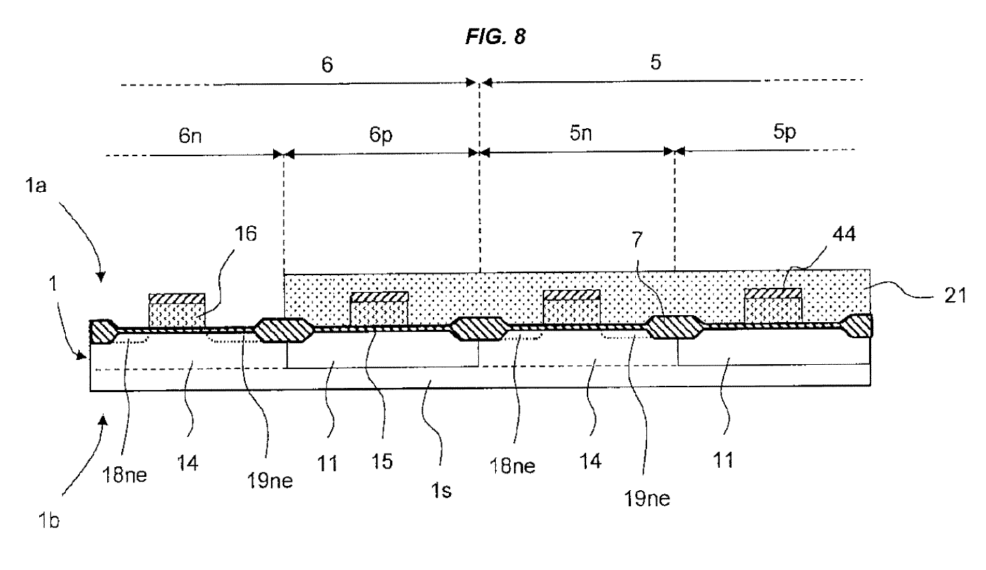

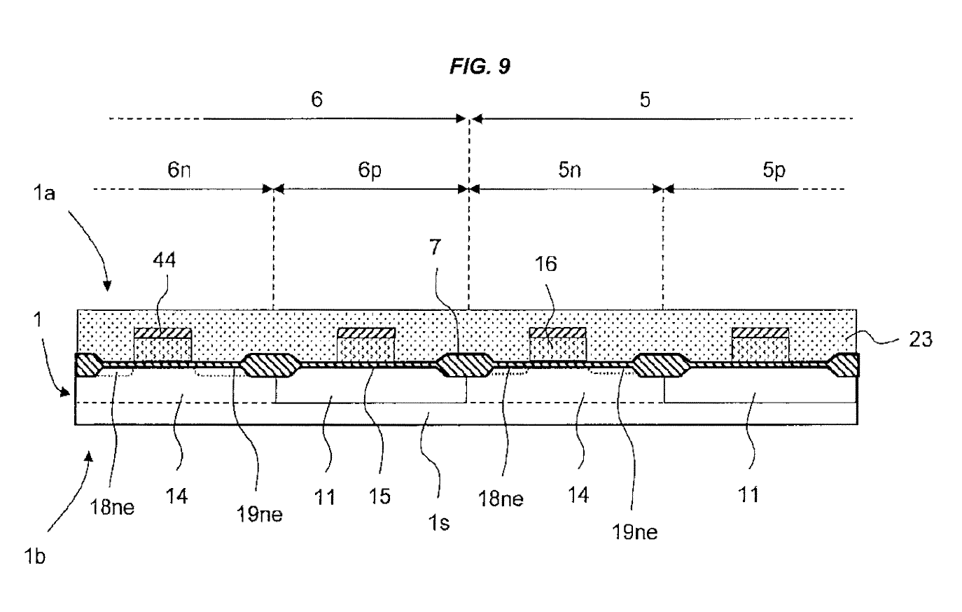

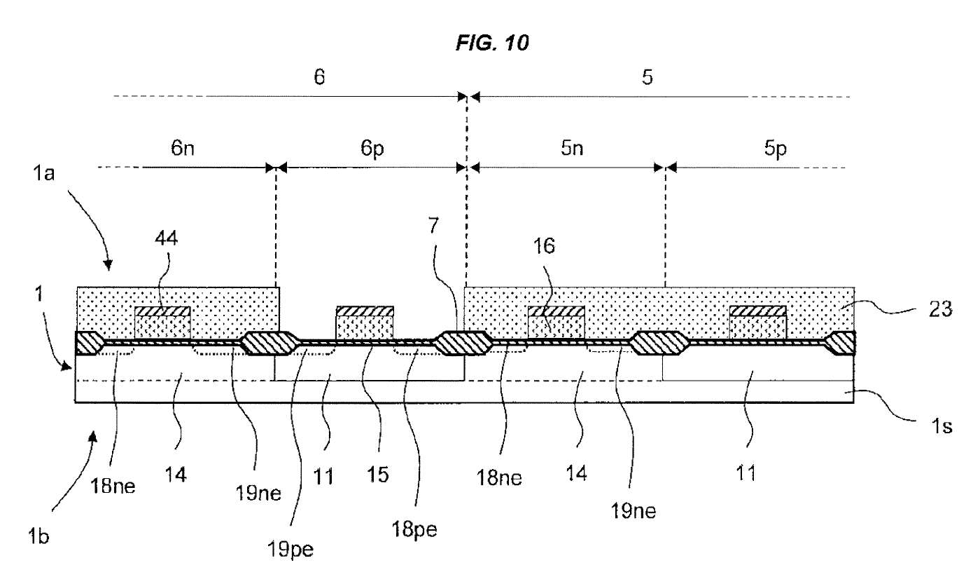

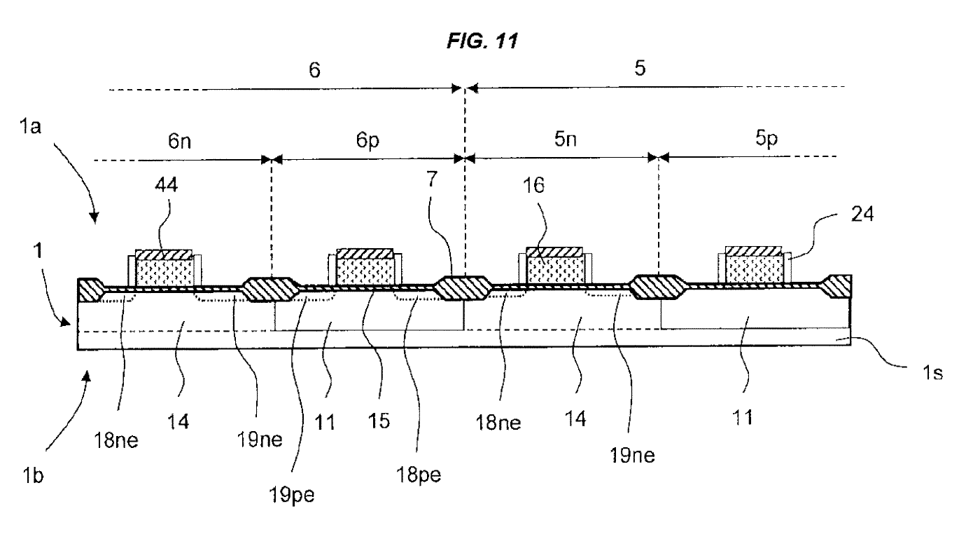

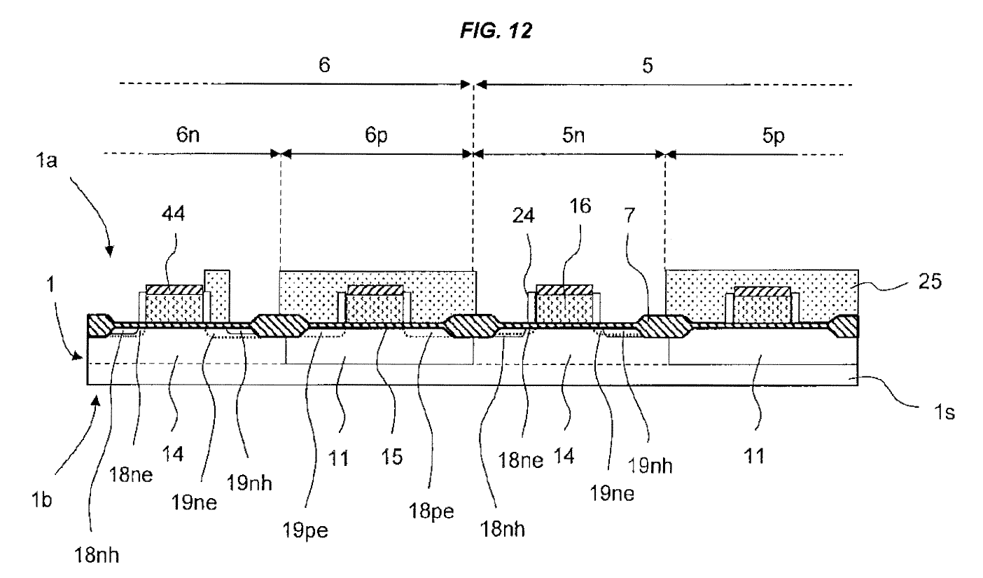

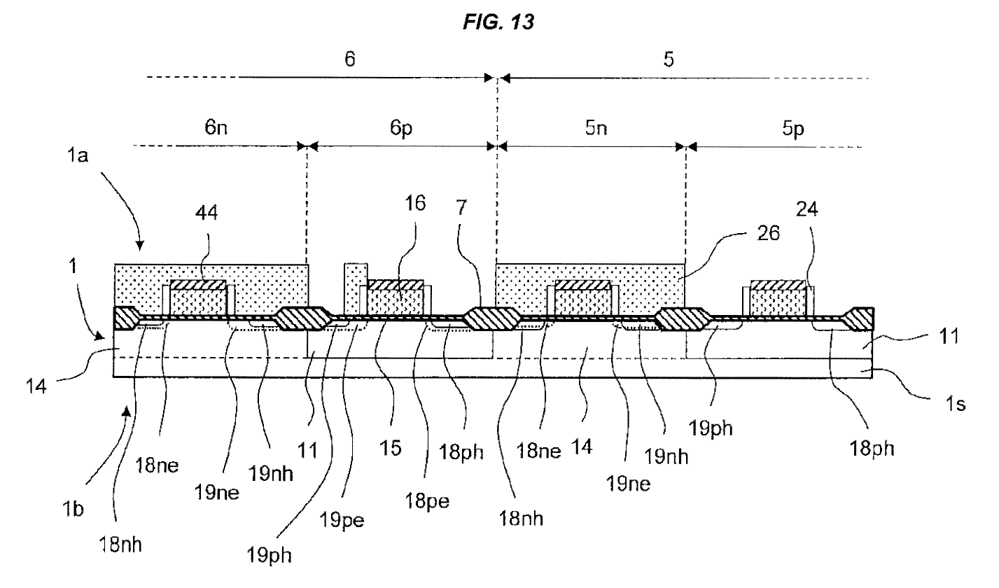

FIG. 2 is a device cross-sectional view for explaining the outline of the semiconductor integrated circuit device and wafer process flow in the manufacturing method of the same according to respective embodiments of the present application (process of inputting a wafer). FIG. 3 is a device cross-sectional view for explaining the outline of the semiconductor integrated circuit device and wafer process flow in the manufacturing method of the same according to respective embodiments of the present application (process of forming a LOCOS insulating film). FIG. 4 is a device cross-sectional view for explaining the outline of the semiconductor integrated circuit device and wafer process flow in the manufacturing method of the same according to respective embodiments of the present application (process of introducing an N-well). FIG. 5 is a device cross-sectional view for explaining the outline of the semiconductor integrated circuit device and wafer process flow in the manufacturing method of the same according to respective embodiments of the present application (process of introducing a P-well). FIG. 6 is a device cross-sectional view for explaining the outline of the semiconductor integrated circuit device and wafer process flow in the manufacturing method of the same according to respective embodiments of the present application (process of forming a gate electrode). FIG. 7 is a device cross-sectional view for explaining the outline of the semiconductor integrated circuit device and wafer process flow in the manufacturing method of the same according to respective embodiments of the present application (process of introducing a low concentration source drain region of an N-channel type low breakdown voltage MISFET). FIG. 8 is a device cross-sectional view for explaining the outline of the semiconductor integrated circuit device and wafer process flow in the manufacturing method of the same according to respective embodiments of the present application (process of introducing a low concentration source drain region of an N-channel type high breakdown voltage MISFET). FIG. 9 is a device cross-sectional view for explaining the outline of the semiconductor integrated circuit device and wafer process flow in the manufacturing method of the same according to respective embodiments of the present application (process of coating a resist film for introducing a low concentration source drain region of a P-channel type high breakdown voltage MISFET). FIG. 10 is a device cross-sectional view for explaining the outline of the semiconductor integrated circuit device and wafer process flow in the manufacturing method of the same according to respective embodiments of the present application (process of introducing a low concentration source drain region of a P-channel type high breakdown voltage MISFET). FIG. 11 is a device cross-sectional view for explaining the outline of the semiconductor integrated circuit device and wafer process flow in the manufacturing method of the same according to respective embodiments of the present application (process of forming a side wall). FIG. 12 is a device cross-sectional view for explaining the outline of the semiconductor integrated circuit device and wafer process flow in the manufacturing method of the same according to respective embodiments of the present application (process of introducing a high concentration source drain region of an N-channel type MISFET). FIG. 13 is a device cross-sectional view for explaining the outline of the semiconductor integrated circuit device and wafer process flow in the manufacturing method of the same according to respective embodiments of the present application (process of introducing a high concentration source drain region of a P-channel type MISFET). FIG. 14 a device cross-sectional view for explaining the outline of the semiconductor integrated circuit device and wafer process flow in the manufacturing method of the same according to respective embodiments of the present application (process of forming a premetal insulating film and forming wiring). On the basis of these, the outline of the semiconductor integrated circuit device and a wafer process in the manufacturing method of the same in respective embodiments of the present application will be explained.

As shown in FIG. 2, firstly, a P-type single crystalline silicon substrate 1 having a specific resistance, for example, of around 1 to 10 Ωcm (here, for example, a wafer having 300φ is used, but a wafer having 450φ or less than 300φ may be used) is prepared.

Next, as shown in FIG. 3, in the boundary part of respective regions of the low breakdown voltage logic circuit region 5 (including a low breakdown voltage N-channel type MISFET-forming region 5n and a low breakdown voltage P-channel type MISFET-forming region 5p), the high breakdown voltage circuit region 6 (including a high breakdown voltage N-channel type MISFET-forming region 6n, and a high breakdown voltage P-channel type MISFET-forming region 6p) etc. over the device main surface la (first main surface) of the wafer 1, a LOCOS (Local Oxidation of Silicon) element isolation insulating film 7 (the thickness is, for example, around 500 nm, the silicon substrate is consumed in around 250 nm on this occasion) is formed, and a surface-oxidized silicon film 8 is formed over the surface of respective active regions surrounded by these. Here, the element isolation insulating film 7 is not restricted to of the LOCOS type, but may be of an STI (Shallow Trench Isolation) type.

Next, as shown in FIG. 4, in a state where the low breakdown voltage N-channel type MISFET-forming region 5n and the high breakdown voltage N-channel type MISFET-forming region 6n are covered with a resist film 9 for introducing an N-well, an N-well region 11 is formed by ion implantation. With regard to the condition of ion implantation, for example, the following can be exemplified as a favorable range; ion species: phosphorous, implantation energy: around 500 keV to 2 MeV, dose quantity: around 1×10¹³/cm² to 1×10¹⁴/cm², and implantation system and implantation tilt angle: 0 degree (vertical implantation system). After the ion implantation, the resist film 9 for introducing an N-well that has become unnecessary is removed.

Next, as shown in FIG. 5, in a state where a low breakdown voltage P-channel type MISFET-forming region 5p and a high breakdown voltage P-channel type MISFET-forming region 6p are covered with a resist film for introducing a P-well 12, a P-well region 14 is formed by ion implantation. With regard to the condition of ion implantation, for example, the following can be exemplified as a favorable range; ion species: boron, implantation energy: around 700 keV to 1 MeV, dose quantity: around 5×10¹²/cm² to 1×10¹³/cm², and implantation system and implantation tilt angle: 0 degree (vertical implantation system). After the ion implantation, the resist film for introducing a P-well 12 that has become unnecessary is removed. Meanwhile, in the stage, a substrate part is that is not the well region 11 or 14 is differentiated from the entire semiconductor substrate 1, if necessary.

Next, as shown in FIG. 6, a thermal oxidation treatment (including oxinitridation treatment etc.) for forming a gate oxidation film 15 (gate insulating film) is carried out. The gate oxidation film 15 has a thickness, for example, of around 10 to 50 nm, as an exemplification of a favorable range. Subsequently, over the approximately entire surface of the device main surface 1a (first main surface) of the wafer 1, a gate polysilicon film 16 is formed by CVD (Chemical Vapor Deposition) etc. using TEOS (Tetraethoxysilane) etc. The gate polysilicon film 16 has a thickness, for example, of around 500 to 1000 nm (basically the thickness of the polysilicon film is determined so that the top face of the polysilicon film is slightly high than the top face of the substrate in the part of recess etc.), as an exemplification of a favorable range. Subsequently, for example, a hard mask film 44 for gate processing (silicon oxide-based insulating film) is formed by CVD etc. using TEOS (Tetraethoxysilane) etc. Subsequently, a polysilicon gate electrode 16 is processed by an ordinary lithography.

Next, as shown in FIG. 7, in a state where mainly parts other than a low breakdown voltage N-channel type MISFET-forming region 5n are covered with a resist film 17 for introducing a low concentration source drain of the low breakdown voltage N-channel type MISFET, a low concentration source region 18ne of the N-channel type MISFET and a low concentration drain region 19ne of the N-channel type MISFET in the low breakdown voltage N-channel type MISFET-forming region 5n are formed by ion implantation. With regard to the condition of ion implantation, for example, the following can be exemplified as a favorable range; ion species: phosphorous, implantation energy: around 50 keV to 150 keV, dose quantity: around 8×10¹²/cm² to 2×10¹⁴/cm², and implantation system and implantation tilt angle: 45 degrees (tilt implantation system in which the total dose quantity is implanted divided into four times from four directions obtained by every 90-degree rotation in the main surface of the wafer). After the ion implantation, the resist film 17 for introducing a low concentration source drain of the low breakdown voltage N-channel type MISFET that has become unnecessary is removed.

Next, as shown in FIG. 8, in a state where mainly parts other than a high breakdown voltage N-channel type MISFET-forming region 6n are covered with a resist film 21 for introducing a low concentration source drain of the high breakdown voltage N-channel type MISFET, a low concentration source region 18ne of the N-channel type MISFET and a low concentration drain region 19ne of the N-channel type MISFET in the high breakdown voltage N-channel type MISFET-forming region 6n are formed by ion implantation. With regard to the condition of ion implantation, for example, the following can be exemplified as a favorable range; ion species: phosphorous, implantation energy: around 50 keV to 250 keV, dose quantity: around 5×10¹²/cm² to 1×10¹⁴/cm², and implantation system and implantation tilt angle: 45 degrees (tilt implantation system in which the total dose quantity is implanted divided into four times from four directions obtained by every 90-degree rotation in the main surface of the wafer). After the ion implantation, the resist film 21 for introducing a low concentration source drain of the high breakdown voltage N-channel type MISFET that has become unnecessary is removed.

Next, as shown in FIG. 9, over the approximately entire surface of the first main surface 1a of the wafer 1, a resist film 23 for introducing a low concentration source drain of the high breakdown voltage P-channel type MISFET is coated.

Next, as shown in FIG. 10, in a state where mainly parts other than a high breakdown voltage P-channel type MISFET-forming region 6p are covered with a resist film 23 for introducing a low concentration source drain of the high breakdown voltage P-channel type MISFET, a low concentration source region 18pe of the P-channel type MISFET and a low concentration drain region 19pe of the P-channel type MISFET in the high breakdown voltage P-channel type MISFET-forming region 6p are formed by ion implantation. With regard to the condition of ion implantation, for example, the following can be exemplified as a favorable range; ion species: boron, implantation energy: around 30 keV to 150 keV, dose quantity: around 5×10¹²/cm² to 1×10¹⁴/cm², and implantation system and implantation tilt angle: 45 degrees (tilt implantation system in which the total dose quantity is implanted divided into four times from four directions obtained by every 90-degree rotation in the main surface of the wafer). After the ion implantation, the resist film 23 for introducing a low concentration source drain of the high breakdown voltage P-channel type MISFET that has become unnecessary is removed.

Next, as shown in FIG. 11, a side wall 24 is formed.

Next, as shown in FIG. 12, in a state where mainly a part of the high breakdown voltage N-channel type MISFET-forming region 6n (offset drain part) and approximately the entire parts of the high breakdown voltage P-channel type MISFET-forming region 6p and the low breakdown voltage P-channel type MISFET-forming region 5p are covered with a resist film 25 for introducing a high concentration source drain of the N-channel type MISFET, a high concentration source region 18nh of the N-channel type MISFET and a high concentration drain region 19nh of the N-channel type MISFET in the high breakdown voltage N-channel type MISFET-forming region 6n and the low breakdown voltage N-channel type MISFET-forming region 5n are formed by ion implantation. With regard to the condition of ion implantation, for example, the following can be exemplified as a favorable range; ion species: arsenic, implantation energy: around 30 keV to 80 keV, dose quantity: around 1×10¹⁵/cm² to 1×10¹⁶/cm², and implantation system and implantation tilt angle: 7 degrees to 45 degrees (tilt implantation system in which the total dose quantity is implanted divided into four times from four directions obtained by every 90-degree rotation in the main surface of the wafer). After the ion implantation, the resist film 25 for introducing a high concentration source drain of the N-channel type MISFET that has become unnecessary is removed.

Next, as shown in FIG. 13, in a state where mainly a part of the high breakdown voltage P-channel type MISFET-forming region 6p (offset drain part) and approximately the entire parts of the low breakdown voltage N-channel type MISFET-forming region 5n and the high breakdown voltage N-channel type MISFET-forming region 6n are covered with a resist film 26 for introducing a high concentration source drain of the P-channel type MISFET, a high concentration source region 18ph of the P-channel type MISFET and a high concentration drain region 19ph of the P-channel type MISFET in the low breakdown voltage P-channel type MISFET-forming region 5p and the high breakdown voltage P-channel type MISFET-forming region 6p are formed by ion implantation. With regard to the condition of ion implantation, for example, the following can be exemplified as a favorable range; ion species: BF₂, implantation energy: around 30 keV to 80 keV, dose quantity: around 1×10¹⁵/cm² to 1×10¹⁶/cm², and implantation system and implantation tilt angle: 7 degrees to 45 degrees (tilt implantation system in which the total dose quantity is implanted divided into four times from four directions obtained by every 90-degree rotation in the main surface of the wafer).

Next, as shown in FIG. 14, over approximately the entire surface of the device surface 1a of the wafer 1, a premetal insulating film 27 (for example, an insulating film containing a silicon oxide-based insulating film as a main constituent element) is formed. In the stage, from the viewpoint of the shape, a state, where the low breakdown voltage N-channel type MISFET Qnc (second N-channel type MISFET), the high breakdown voltage N-channel type MISFET Qnh (first N-channel type MISFET), the low breakdown voltage P-channel type MISFET Qpc (first P-channel type MISFET) and the high breakdown voltage P-channel type MISFET Qph (first P-channel type MISFET) are approximately completed, is brought about. Here, if necessary, CMP (Chemical Mechanical Polishing) or the like is carried out to flatten the surface. Subsequently, by anisotropic dry etching by ordinary lithography or the like, a contact hole is formed in the premetal insulating film 27. Subsequently, a tungsten plug 28 is embedded into the contact hole to thereby form a lower layer wiring 29 (for example, aluminum-based wiring) over the premetal insulating film 27. Subsequently, over the premetal insulating film 27 and the lower layer wiring 29, an interlayer insulating film 31 (for example, an insulating film containing a silicon oxide-based insulating film as a main constituent element) is formed. Subsequently, a via hole is formed in the interlayer insulating film 31 by anisotropic dry etching by ordinary lithography, or the like. Subsequently, the tungsten plug 28 is embedded into the via hole. Such process is repeated, and, finally, a bonding pad 32 and a final passivation film 33 are formed.

Meanwhile, the low breakdown voltage N-channel type MISFET Qnc (second N-channel type MISFET) and the low breakdown voltage P-channel type MISFET Qpc (first P-channel type MISFET) constitute a pair with each other in a CMOS (CMIS) unit circuit, and the high breakdown voltage N-channel type MISFET Qnh (first N-channel type MISFET) and the high breakdown voltage P-channel type MISFET Qph (first P-channel type MISFET) constitute a pair (first CMISFET pair) with each other in a CMOS (CMIS) unit circuit. That is, they constitute a CMOS (CMIS) inverter, a CMOS (CMIS)-NOR circuit, a CMOS (CMIS)-NAND circuit etc.

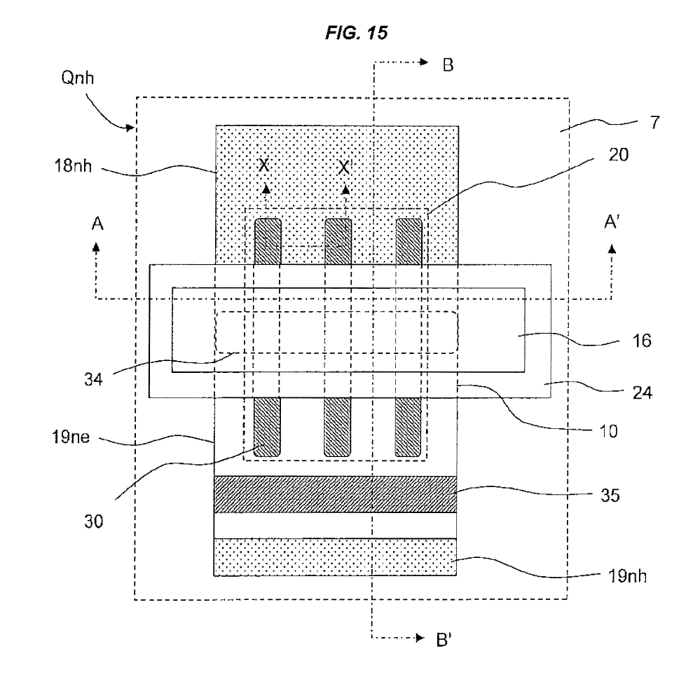

3. Explanation of basic structure of the device common to semiconductor integrated circuit devices of respective embodiments of the present application (mainly FIGS. 15 to 17)

In this section, in order to explain the basic feature of structure of the high breakdown voltage MOSFET (high breakdown voltage MISFET) constituting the CMOS circuit or the CMIS circuit of respective embodiments, an N channel high breakdown voltage MOSFET will be extracted and explained. Meanwhile, a P channel high breakdown voltage MOSFET is approximately the same in the structure, although there are slight differences in parameters to such degree that is usually expected.

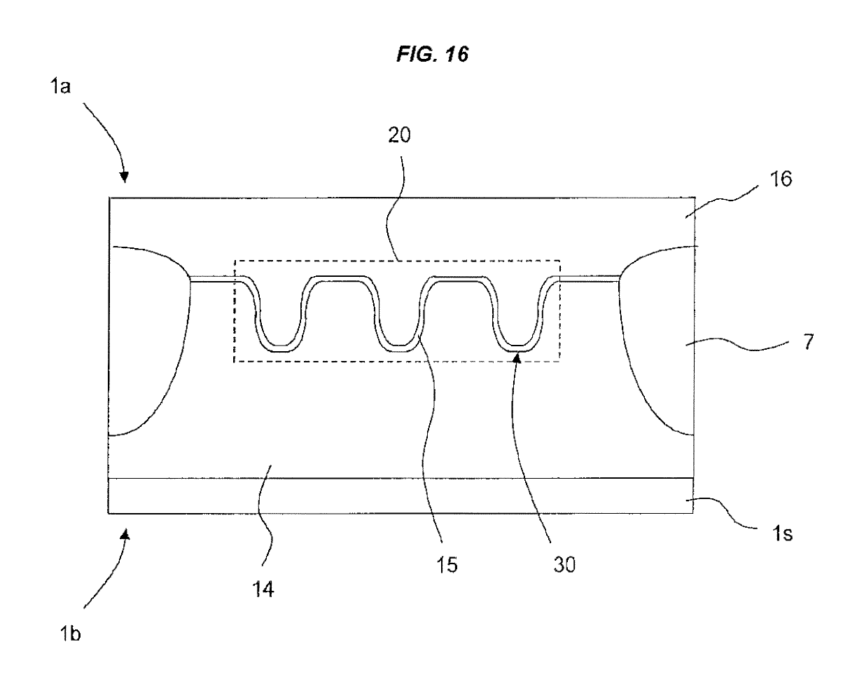

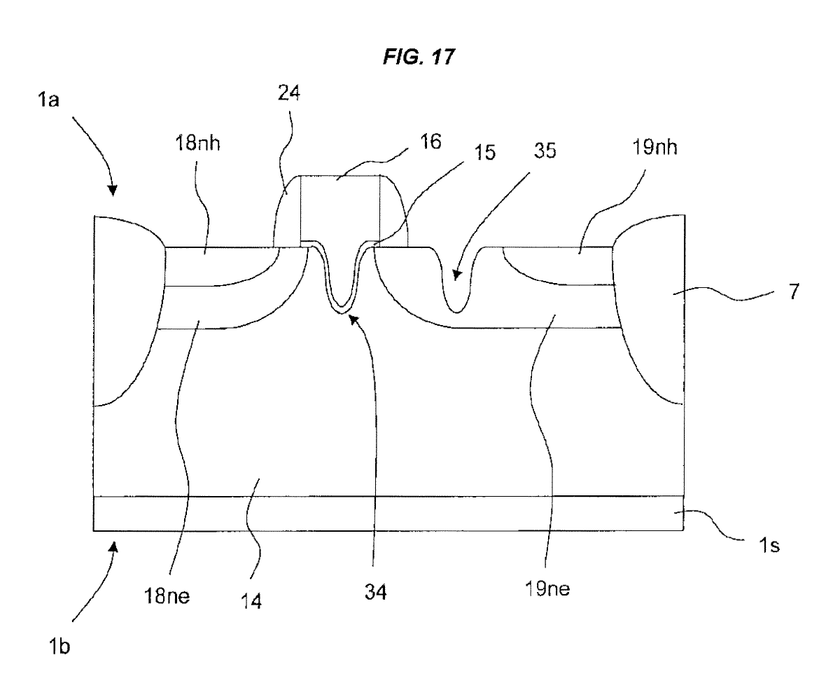

FIG. 15 is a local top face view of a semiconductor substrate showing the basic structure of the device common to the semiconductor integrated circuit devices of respective embodiments of the present application. FIG. 16 is a local cross-sectional view of the device corresponding to the A-A′ cross-section in FIG. 15. FIG. 17 is a local cross-sectional view of the device corresponding to the B-B′ cross-section in FIG. 15. On the basis of these, the following is the explanation of basic structure of the device common to semiconductor integrated circuit devices of respective embodiments of the present application.

As shown in FIGS. 15 to 17, the active region is surrounded by the LOCOS element isolation insulating film 7, and the active region is divided into one on the source side and one on the drain side by a gate electrode 16 (directly under it, the channel region 10 lies, the channel width is, for example, around 10 μm). The periphery of the gate electrode 16 (the gate length is, for example, around 1 μm) is surrounded by a side wall 24, and, in the channel region 10 under the gate electrode 16, a recess channel part 34 (a trench in the gate width direction, the trench width is, for example, around 0.5 μm) is provided along the gate width direction. In the surface of the channel region 10, there is provided a ripple part 20 (wave undulation) constituted of plural trenches along the gate length direction, that is, ripple bottom parts 30 (wave undulation bottom part) and long and narrow highlands therebetween, that is, a wave undulation channel (ripple channel). If the wave undulation 20 is considered to be a traveling wave (on this occasion, the wavelength, that is, the pitch of the ripple is, for example, around 0.8 μm), the traveling direction is the gate width direction. Therefore, when the alignment of the wave undulation 20 is to be expressed, the case shown in FIG. 15 is denoted as “the wave undulation or ripple along the gate width direction” etc. Furthermore, in the surface of offset part of the low concentration drain region 19ne of the N-channel type MISFET, a trench along the gate width direction, that is, a recess drain part 35 (trench width thereof is, for example, around 0.5 μm) is provided. Meanwhile, with regard to each width of the ripple bottom part 30 and the long and narrow highland, for example, around 0.4 μm is cited as a favorable example. The step between the ripple bottom part 30 and the long and narrow highland is referred to as “wave height.”

The introduction of such ripple can substantially increase the channel width. Moreover, the introduction of the recess channel part gives such effect as substantially expanding the channel length. In the same manner, the introduction of the recess drain can substantially expand the length of the offset drain.

4. Explanation of structure etc. of a CMOS configuration in the semiconductor integrated circuit device of a first embodiment of the present application (mainly FIG. 18)

The example of this Section is one obtained by improving the example in Section 3 so as to conform furthermore to a practical CMOS configuration. That is, it adopts ways and means for improving characteristics including the PN balance of the wave undulation (P-channel and N-channel have approximately the same wave height but different wave lengths) and the periphery structure of contact. Meanwhile, the basic structure of cross-section is approximately the same as that in FIGS. 16 and 17 and, therefore, only different parts will be explained in principle below.

FIG. 18 is a local top face view of a semiconductor substrate showing the device structure of CMOS configuration in the semiconductor integrated circuit device of the first embodiment of the present application. On the basis of this, the structure of CMOS configuration in the semiconductor integrated circuit device of the first embodiment of the present application will be explained.

As shown in FIG. 18, in a way similar to that in Section 3, in respective high breakdown voltage N-channel type MISFET Qnh (first N-channel type MISFET) and high breakdown voltage P-channel type MISFET Qph (first P-channel type MISFET), the active region is surrounded by the LOCOS element isolation insulating film 7, and the active region is divided into the source side (a first source region and a second source region) and the drain side (a first drain region and a second drain region) by gate electrodes 16n and 16p (directly under it, the channel region 10, that is, a first channel region 10n and a second channel region 10p lie). The periphery of gate electrodes 16n and 16p (gate length is, for example, around 1 μm) is surrounded by a side wall 24, and, in channel regions 10n and 10p under gate electrodes 16n and 16p, a recess channel part 34 (trench in the gate width direction, the trench width is, for example, around 0.5 μm), that is, a first in-channel recess region and a second in-channel recess region are provided along the gate width direction (channel width is, for example, around 10 μm). Moreover, in the surface of channel regions 10n and 10p, there are provided ripple parts 20n and 20p (wave undulation, that is, a first wave undulation 20n and a second wave undulation 20p) constituted of plural trenches along the gate length, that is, ripple bottom parts 30n and 30p (wave undulation bottom parts) and long and narrow highlands therebetween, that is, the wave undulation channel (ripple channel). Moreover, in the surface of offset part of respective low concentration drain regions 19ne and 19pe of the high breakdown voltage N-channel type MISFET Qnh and the high breakdown voltage P-channel type MISFET Qph, there is provided a trench along the gate width direction, that is, recess drain part 35 (trench width thereof is, for example, around 0.5 μm), that is, a recess region in an N-type drain and a recess region in a P-type drain.

Here, the high breakdown voltage N-channel type MISFET Qnh and the high breakdown voltage P-channel type MISFET Qph have different pitches (wavelengths) of wave undulation 20n and 20p each other. That is, the pitch of wave undulation 20n of the high breakdown voltage N-channel type MISFET Qnh (for example, around 0.8 μm, that is, widths of both the bottom part and the highland are around 0.4 μm) is shorter than the pitch of wave undulation 20p of the high breakdown voltage P-channel type MISFET Qph (for example, around 1.4 μm, that is, widths of both the bottom part and the highland are around 0.7 μm).

As described above, by changing the pitch, of ripple part between the N-channel side and the P-channel side, the exposure of (110) plane, which deteriorates the electron mobility on the N-channel side, can be avoided. That is, since the pitch is narrow on the N-channel side, the side surface is a comparatively gradually inclined surface, the exposure probability of (110) plane, which tends to be exposed on a steeply inclined surface, can be lowered.

Moreover, ripple bottom parts (wave undulation bottom parts) 30n and 30p are extended to a contact part 36 (the bottom part of the tungsten plug 28), that is, to the contact region on the drain side.

Furthermore, on the source side and drain side, the contact part 36 is provided for both ripple bottom parts (wave undulation bottom parts) 30n and 30p, and the long and narrow highland therebetween.

These measures of contact region surroundings can reduce ON resistance.

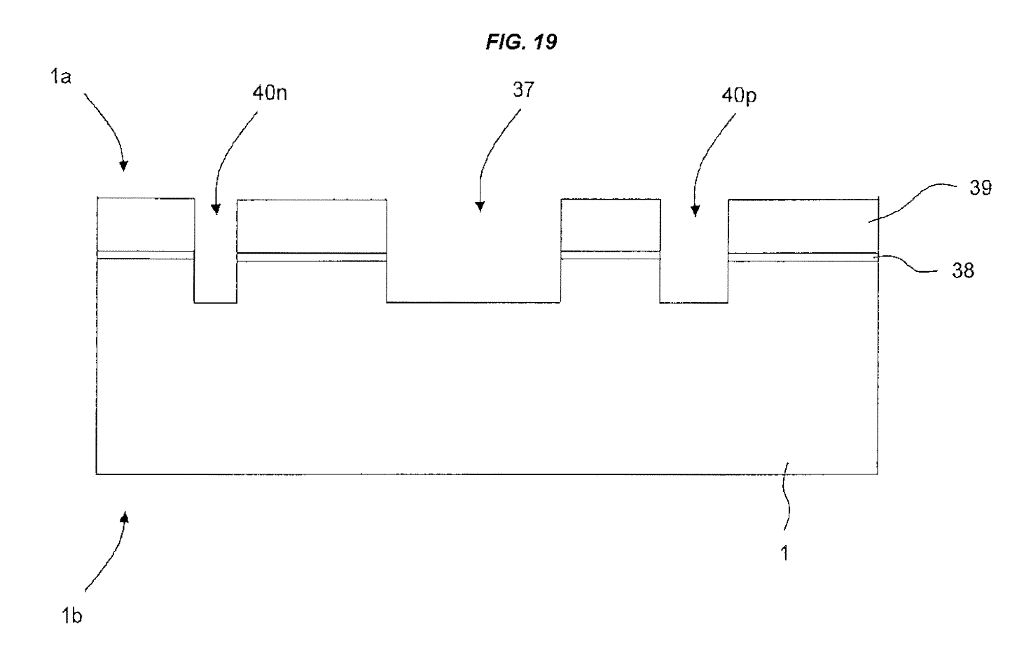

5. Explanation of the relevant part process flow in the manufacturing method of a semiconductor integrated circuit device of the first embodiment of the present application (mainly FIGS. 19 to 29, FIG. 51)

In this Section, an example of the principal part of a manufacturing process that realizes the structure explained in Section 4 will be explained. The principal part of the manufacturing process corresponds to FIGS. 2 to 6 of the entire process explained in Section 2.

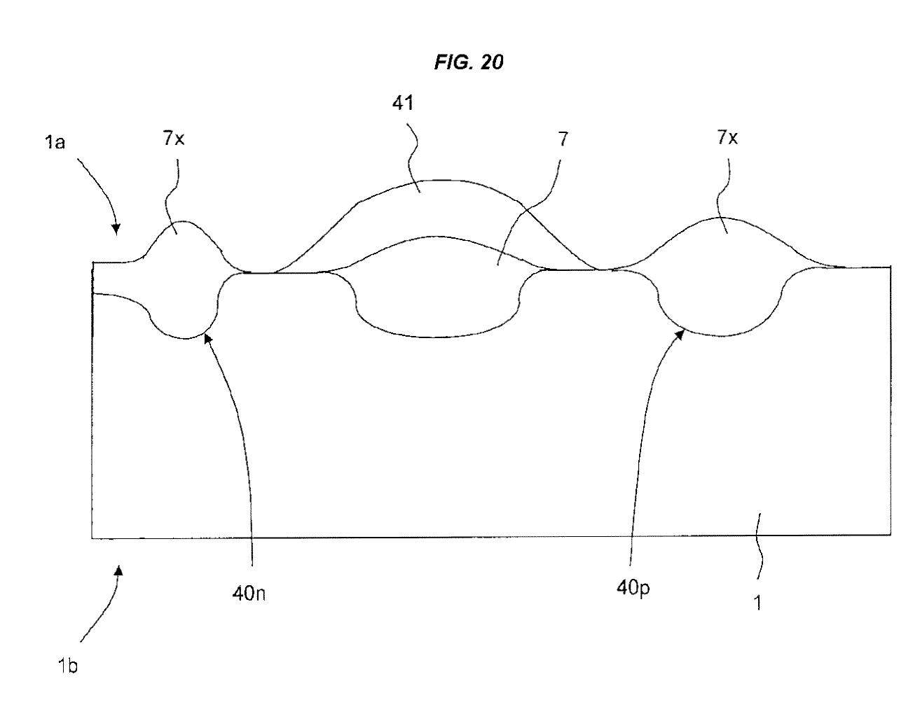

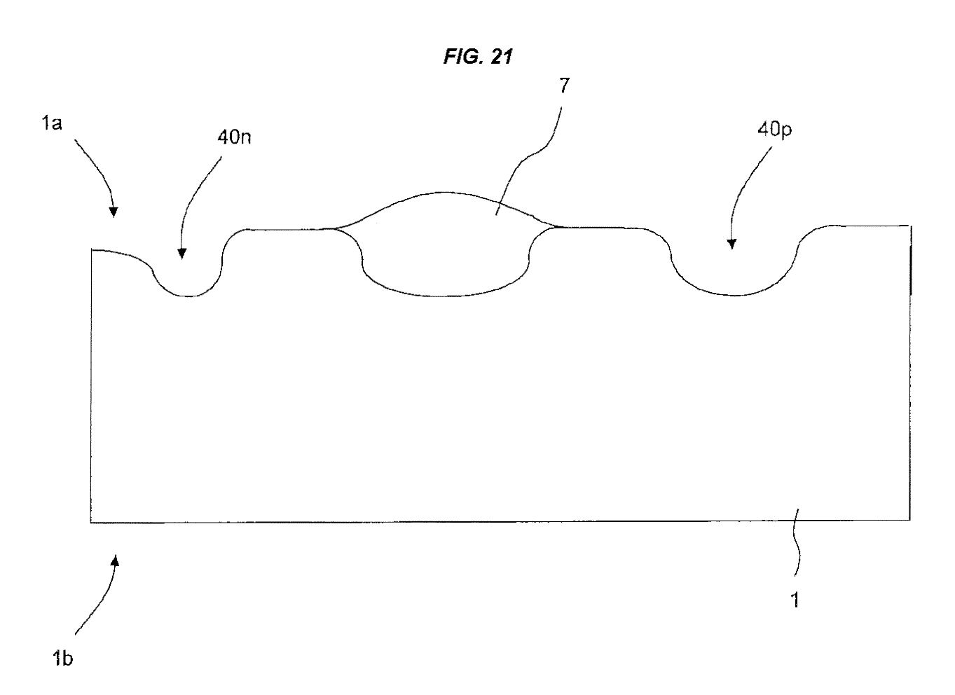

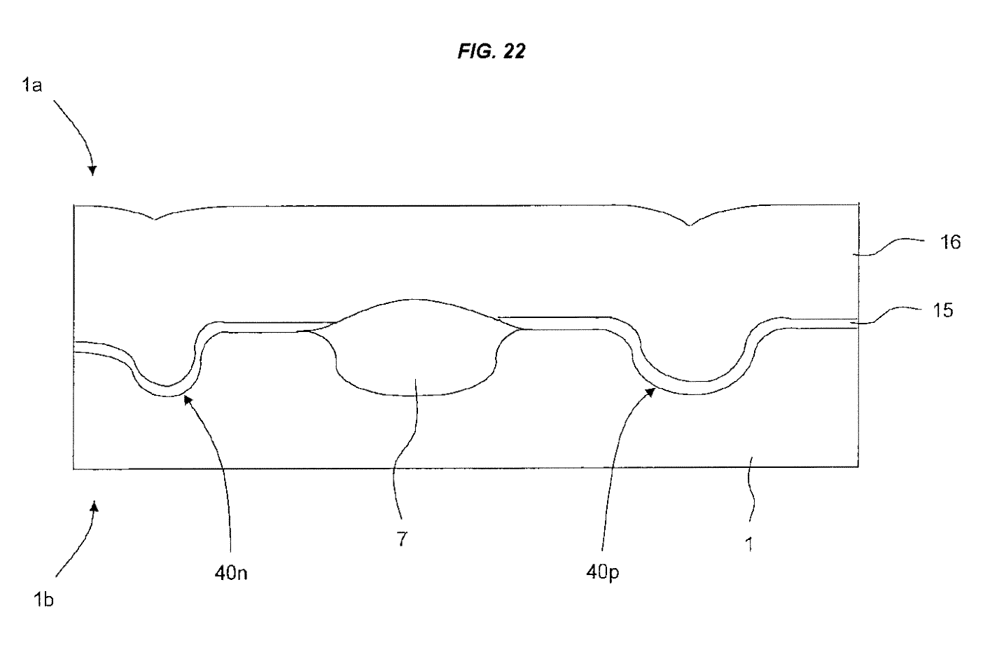

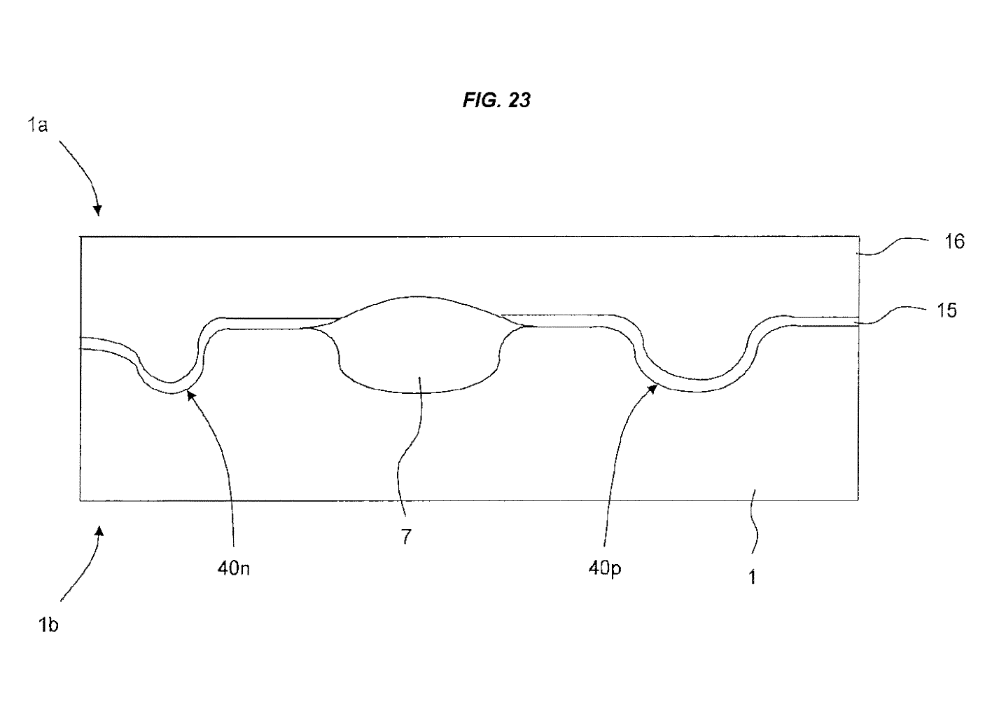

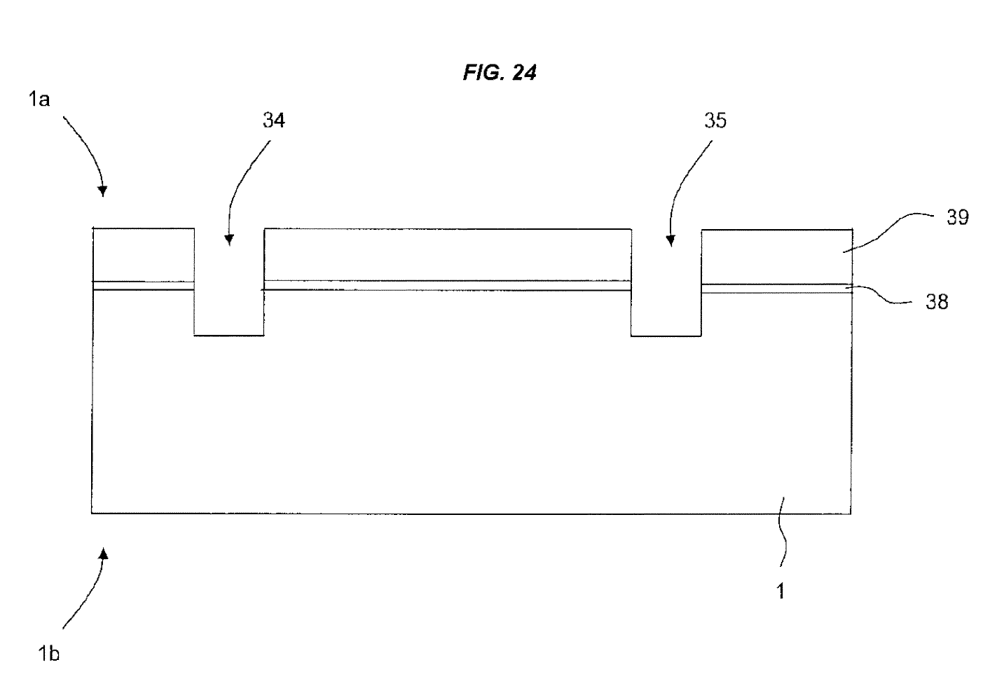

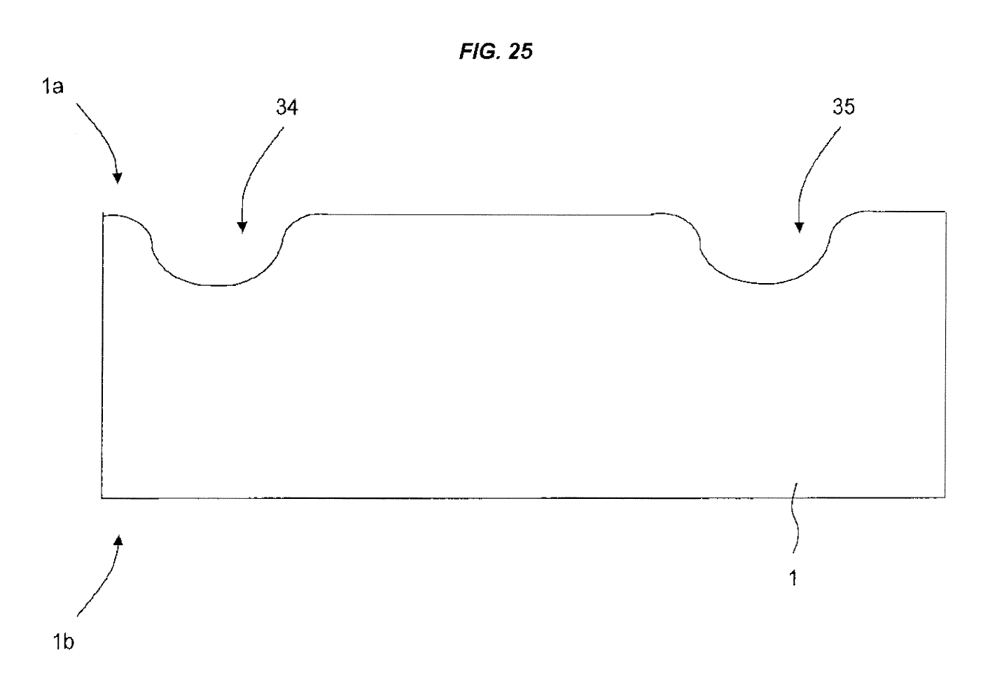

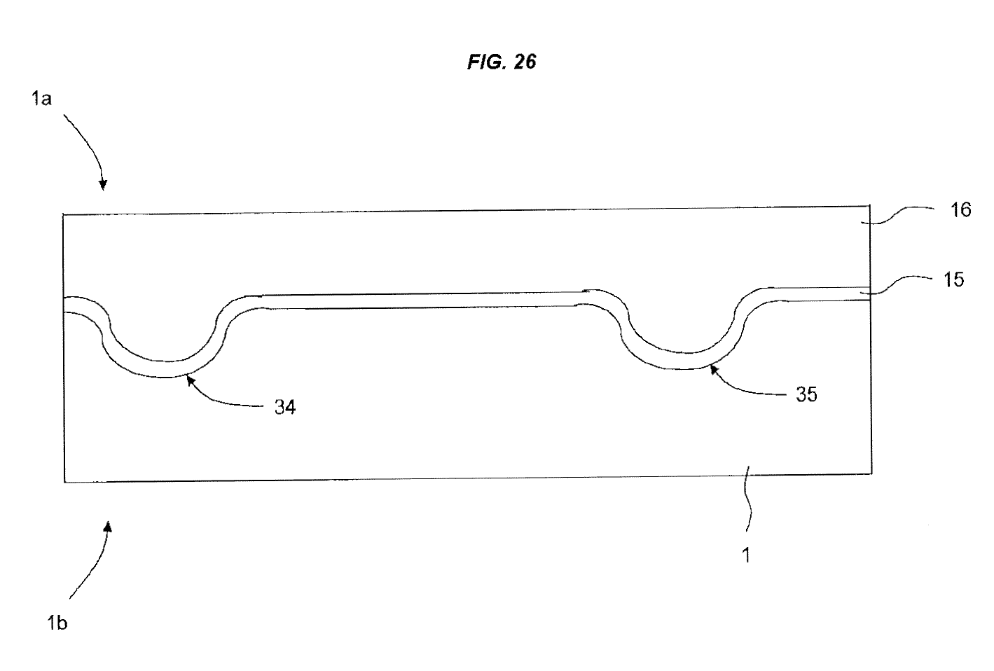

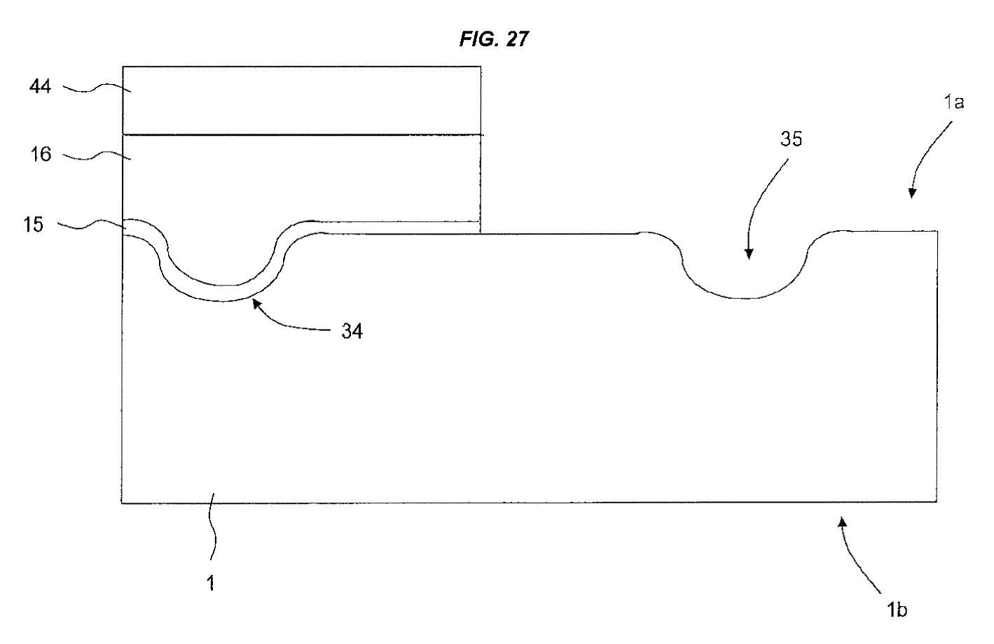

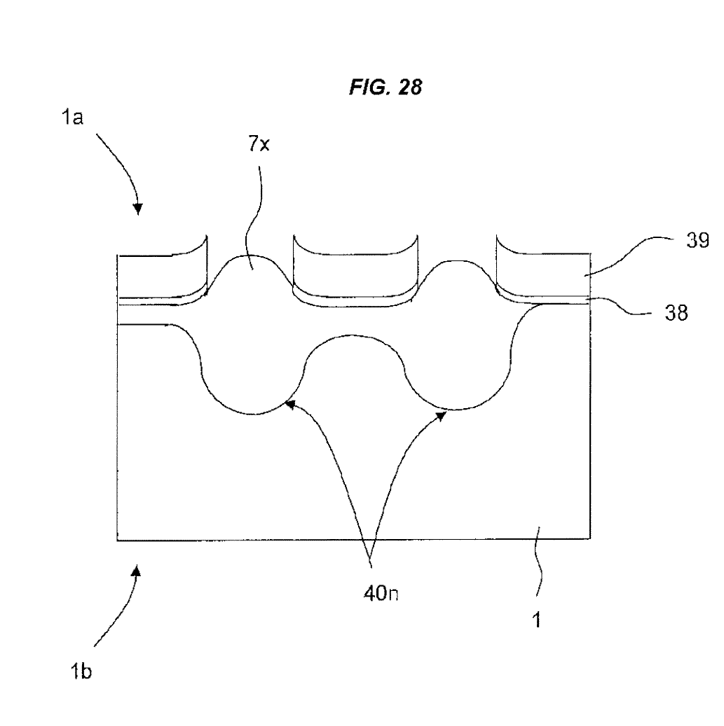

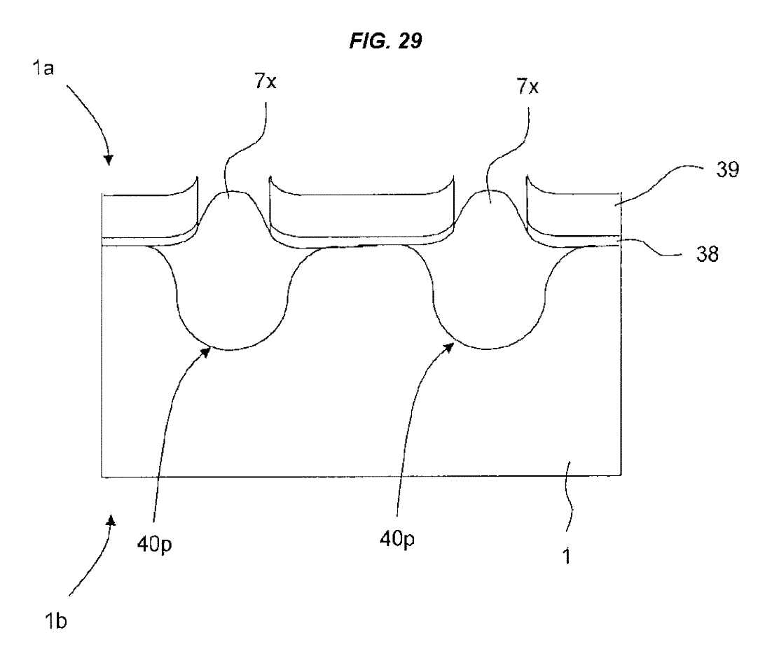

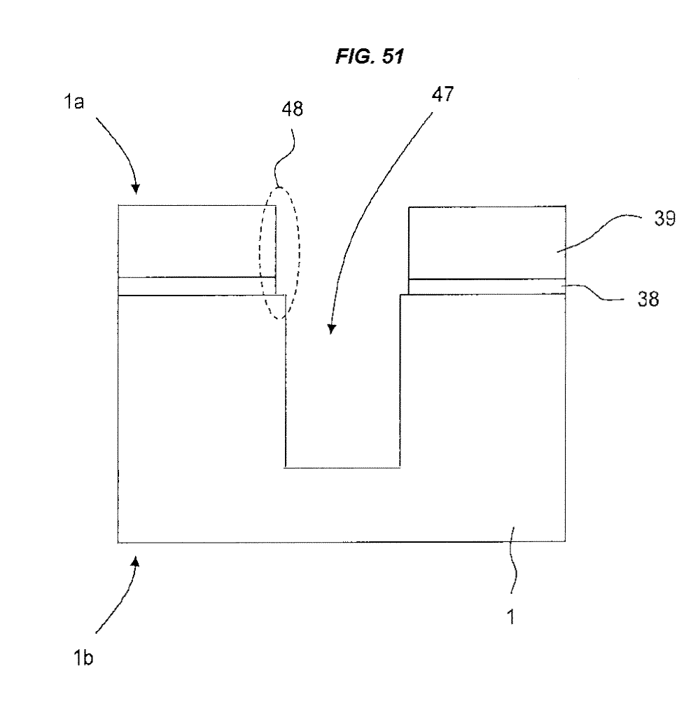

FIG. 19 is a local cross-sectional view of a device explaining a relevant part process flow in the C-C′ cross-section in FIG. 18 (process of forming various types of trenches before LOCOS oxidation). FIG. 20 is a local cross-sectional view of a device explaining a relevant part process flow in the C-C′ cross-section in FIG. 18 (process of LOCOS oxidation and post-treatment). FIG. 21 is a local cross-sectional view of a device explaining a relevant part process flow in the C-C′ cross-section in FIG. 18 (removal of an oxide film in the trench for ripple). FIG. 22 is a local cross-sectional view of a device explaining a relevant part process flow in the C-C′ cross-section in FIG. 18 (process of oxidizing a gate and forming a gate polysilicon film). FIG. 23 is a local cross-sectional view of a device explaining a relevant part process flow in the C-C′ cross-section in FIG. 18 (process of flattening the upper face of the gate polysilicon). FIG. 24 is a local cross-sectional view of a device explaining a relevant part process flow in the D-D′ cross-section in FIG. 18 (process of forming various types of trenches before LOCOS oxidation). FIG. 25 is a local cross-sectional view of a device explaining a relevant part process flow in the D-D′ cross-section in FIG. 18 (removal of an oxide film in a trench for recess). FIG. 26 is a local cross-sectional view of a device explaining a relevant part process flow in the D-D′ cross-section in FIG. 18 (process for flattening the upper face of the gate polysilicon film). FIG. 27 is a local cross-sectional view of a device explaining a relevant part process flow in the D-D′ cross-section in FIG. 18 (process of patterning the gate polysilicon film). FIG. 28 is a local cross-sectional view of a device explaining a relevant part process flow in the E-E′ cross-section in FIG. 18 (process of LOCOS oxidation). FIG. 29 is a local cross-sectional view of a device explaining a relevant part process flow in the F-F′ cross-section in FIG. 18 (process of LOCOS oxidation). FIG. 51 is a cross-sectional view of a device of parts corresponding to the ripple trench, various types of recess trenches, the element isolation trench, etc. formed in FIGS. 19, 24, etc. for explaining the recession treatment of the insulating film for LOCOS oxidation. On the basis of these, the relevant part process flow in the manufacturing method of a semiconductor integrated circuit device of the first embodiment of the present application will be explained.

On the basis of FIGS. 19 to 23, FIGS. 24 to 27, and FIGS. 28 and 29, the relevant part process flow in the C-C′ cross-section, D-D′ cross-section, E-E′ cross-section, and F-F′ cross-section in FIG. 18 will be explained. Firstly, as shown in FIGS. 19 and 24, over approximately the entire device surface la of wafer 1 in the state in FIG. 2, a silicon oxide-based insulating film 38 (specifically, a silicon oxide film or a silicon oxynitride film) is formed, and, over approximately the entire surface thereof, a silicon nitride-based insulating film 39 (specifically, a silicon nitride film) is formed, to thereby forming an insulating film for LOCOS oxidation. Examples of favorable ranges of the thickness include around 5 nm to 50 nm for the silicon oxide-based insulating film 38, and around 50 nm to 200 nm for the silicon nitride-based insulating film 39.

After that, the insulating film for LOCOS oxidation is patterned, for example, by ordinary lithography and anisotropic etching. Subsequently, the insulating film for LOCOS oxidation is used as a mask to form simultaneously trenches such as a trench 40n for n-channel side ripple, a trench 40p for p-channel side ripple, an element isolation trench 37, a recess channel part 34 and a recess drain part 35 (thickness is, for example, around 300 nm, favorable range is, for example, 50 nm to 500 nm) for the substrate 1 by dry etching etc. Accordingly, all these trenches have the same depth.

Next, the recession treatment (recession quantity is, for example, around 30 nm, favorable range is, for example, around 5 nm to 50 nm) is carried out for insulating films for LOCOS oxidation neighboring respective trenches of the ripple part, various recess trenches, element isolation trenches (various trenches) etc. formed in FIGS. 19 and 24. The recession treatment gives such effect as rounding the edge of the silicon substrate at the upper edge part of respective trenches such as ripple parts, gives such effect as hardly allowing undesired crystal planes to be exposed, and, in addition, adjusting the shape of the trench upper cross-section so as to have a favorable curvature in other trenches.

That is, as shown in FIG. 51, the silicon nitride-based insulating film 39 is subjected to a wet treatment with hot phosphoric acid etc. to thereby be moved back from the edge of various trenches. Subsequently, the silicon oxide-based insulating film 38 is dry-etched using the silicon nitride-based insulating film 39 as a mask to thereby move back the silicon oxide-based insulating film 38, too, form the edge of various trenches, to thereby form a recession part 48 of the insulating film for LOCOS oxidation.

Next, as shown in FIGS. 28 and 29, for a trench 40n for n-channel side ripple, a trench 40p for p-channel side ripple, an element isolation trench 37, trenches of a recess channel part 34 and a recess drain part 35, etc., a LOCOS element isolation insulating film 7 or a thermal oxidation silicon film (rounding oxidation film) 7x in various trenches formed simultaneously with the LOCOS oxidation film is formed by LOCOS oxidation (thickness is, for example, around 300 nm to 600 nm) (as the oxidation condition, wet oxidation at 900° C. to 1200° C. can be exemplified). Subsequently, the silicon nitride-based insulating film 39 is entirely removed by a wet treatment with hot phosphoric acid etc., and, furthermore, the silicon oxide-based insulating film 38 is removed by a hydrofluoric acid-based wet treatment.

Next, as shown in FIG. 20, in the state where only over the LOCOS element isolation insulating film 7 is covered with an etching-resistant material film 41 (for example, a resist film or a silicon nitride film), the thermally oxidized silicon film 7x in various trenches that is formed simultaneously with the LOCOS oxidation film and lies in parts not covered with the etching-resistant material film 41 is removed to thereby form, as shown in FIGS. 21 and 25, a trench 40n for ripple on the n-channel side, a trench 40p for ripple on the p-channel side, trenches of the recess channel part 34 and recess drain part 35, etc. having a round shape.

Next, as shown in FIG. 22, the formation of the gate insulating film 15 by thermal oxidation etc. in the active region (part where the LOCOS element isolation insulating film 7 is absent) of the device surface 1a of the wafer 1 gives the state in FIG. 3. Subsequently, over approximately the entire surface of the device surface 1a of the wafer 1, a polysilicon film 16 (thickness is, for example, around 500 nm to 1000 nm, and is sufficient when the top face of polysilicon becomes higher than the top face of the substrate in various trenches (ripple, recess, etc.)) to be a polysilicon gate electrode is formed.

Next, as shown in FIGS. 23 and 26, a flattening treatment is carried out for the top face of the polysilicon film 16 by CMP (Chemical Mechanical Polishing) etc.

Next, as shown in FIG. 27 (corresponding to FIG. 6), over the polysilicon film 16, a hard mask film 44 for gate processing (which has necessarily a thickness larger than or equal to the depth of various trenches, and, therefore, when the trench has a thickness of around 300 nm, for example, the thickness is around 400 nm) is formed, and, after that, the patterning for gate is carried out by ordinary lithography.

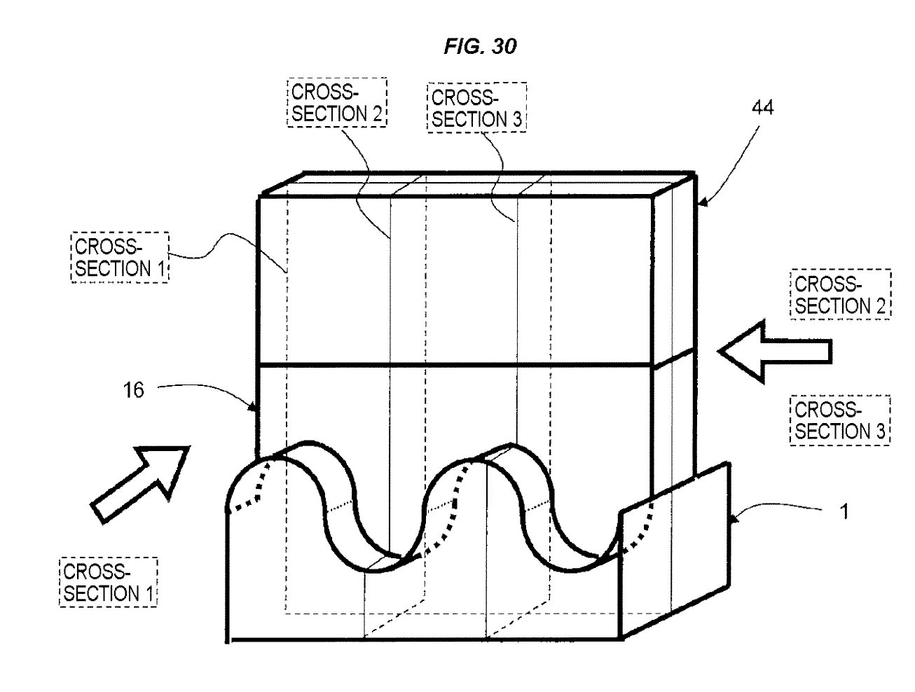

6. Explanation of a side wall process common to semiconductor integrated circuit devices of respective embodiments of the present application (mainly FIGS. 30 to 36)

In this Section, the process of forming a side wall explained in FIG. 11 and a detailed structure (part that is omitted in Section 2) will be explained in detail. Here, high breakdown voltage MISFETs (Qnh, Qph) will be taken as examples for the explanation.

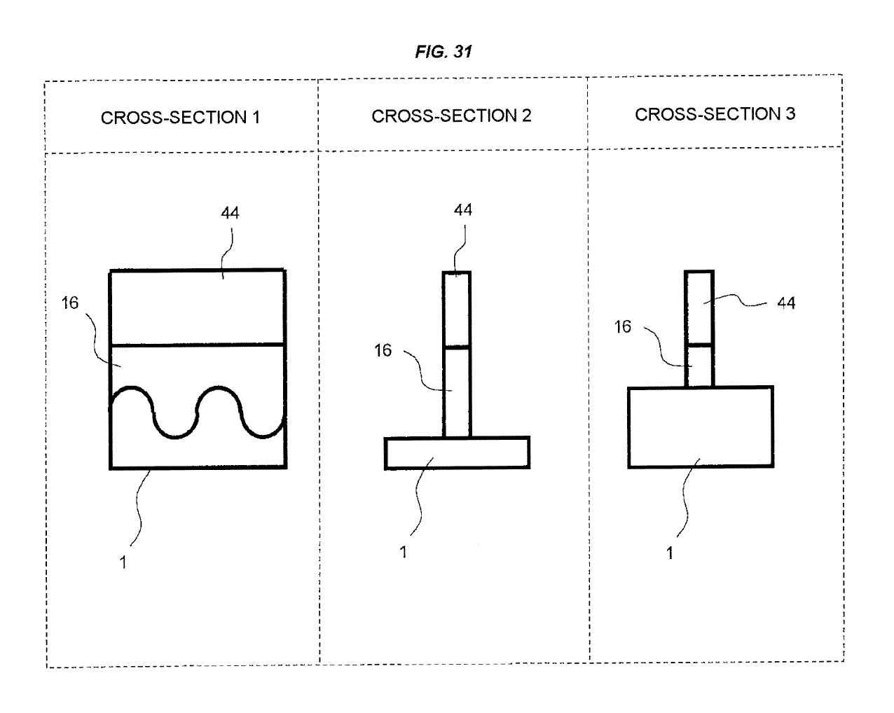

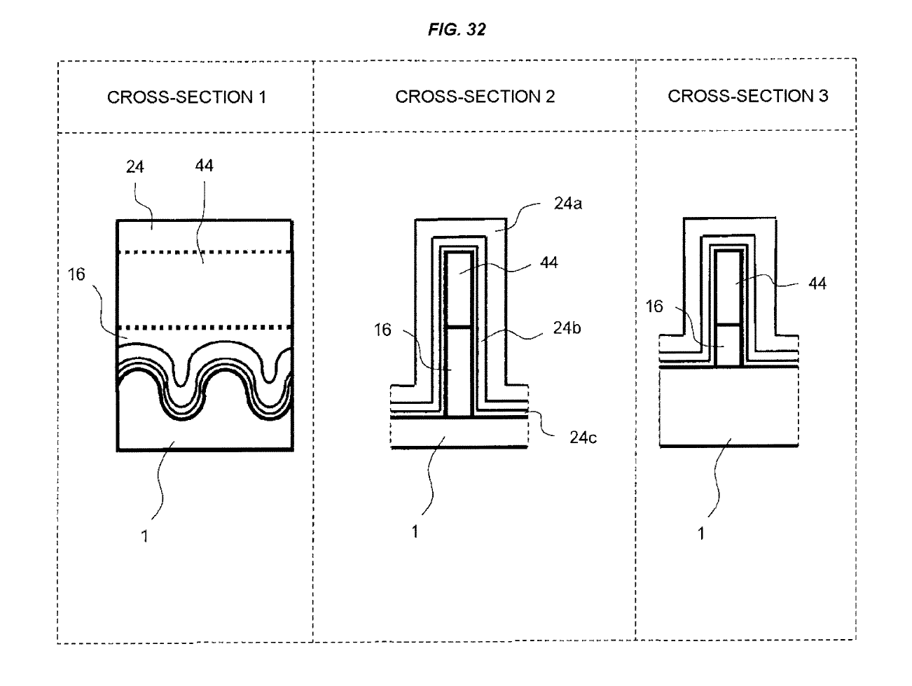

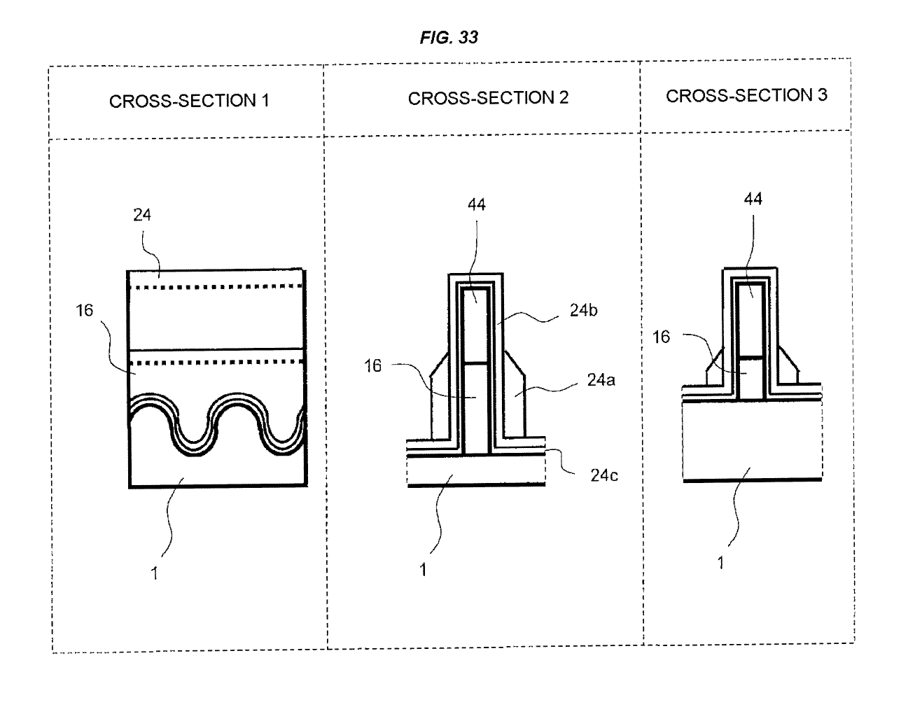

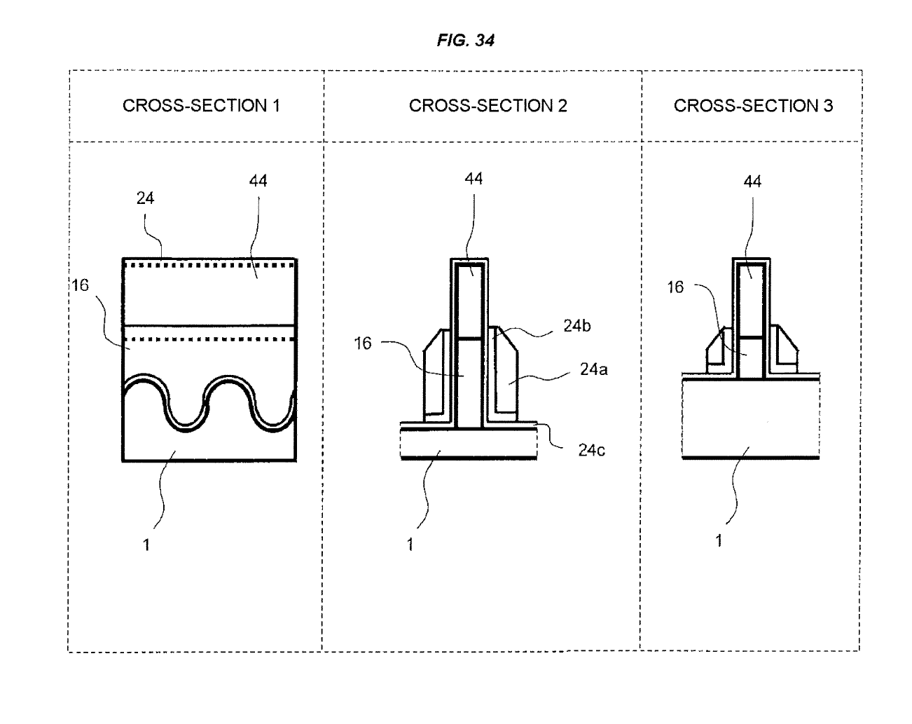

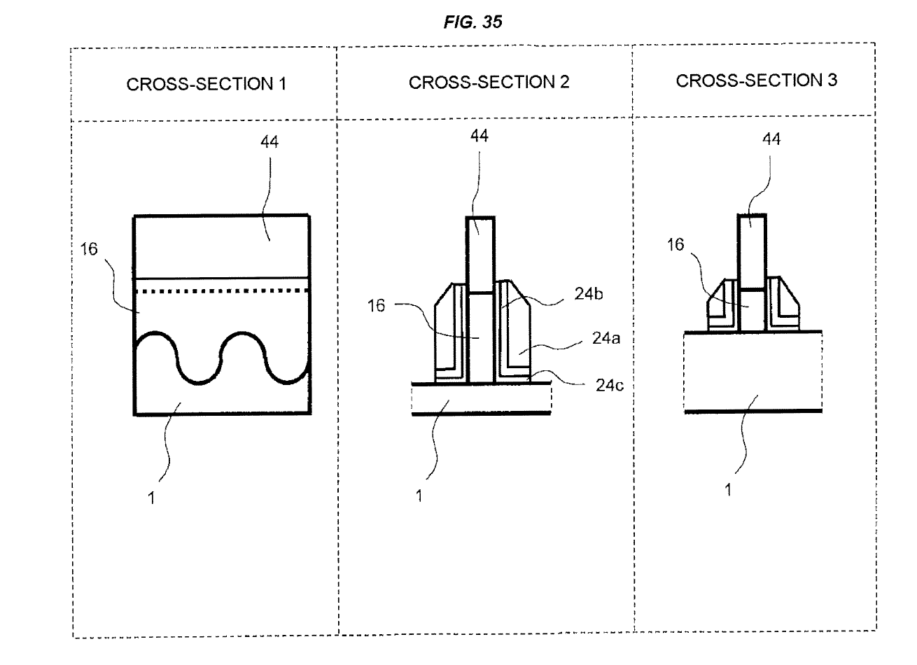

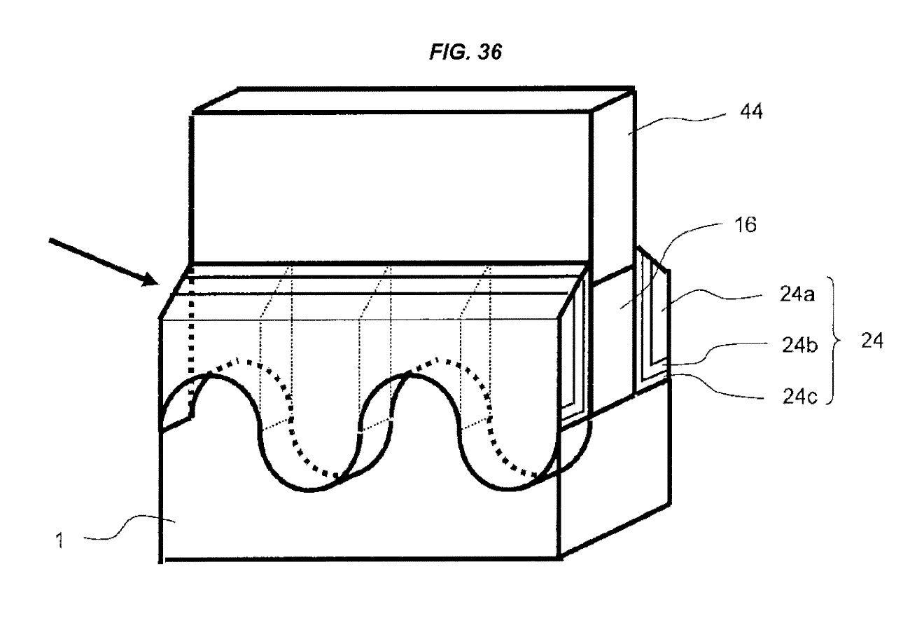

FIG. 30 is a perspective view of the periphery of the gate electrode for explaining a side wall process common to semiconductor integrated circuit devices of respective embodiments of the present application (before the formation of the side wall). FIG. 31 is a cross-sectional view of the periphery of the gate electrode corresponding to cross-sections 1 to 3 in FIG. 30 (before the formation of the side wall). FIG. 32 is a cross-sectional view of the periphery of the gate electrode corresponding to cross-sections 1 to 3 in FIG. 30 (process of forming the side wall film). FIG. 33 is a cross-sectional view of the periphery of the gate electrode corresponding to cross-sections 1 to 3 in FIG. 30 (process of dry-etching the upper layer film of the side wall film). FIG. 34 is a cross-sectional view of the periphery of the gate electrode corresponding to cross-sections 1 to 3 in FIG. 30 (process of dry-etching the intermediate film of the side wall film). FIG. 35 is a cross-sectional view of the periphery of the gate electrode corresponding to cross-sections 1 to 3 in FIG. 30 (time point of completing the dry etching process of the lower layer film of the side wall film). FIG. 36 is a perspective view of the periphery of the gate electrode for explaining the side wall process common to semiconductor integrated circuit devices of respective embodiments of the present application (time point of completing the dry etching process of the lower layer film of the side wall film). That is, FIG. 30 (perspective view) corresponds to the state in FIG. 6, and respective cross-sections (cross-sections 1 to 3) in FIG. 30 (perspective view) are shown for respective steps in FIGS. 31 to 35. Meanwhile, FIG. 36 (perspective view) corresponds to the state in FIG. 11. On the basis of these, the side wall process common to semiconductor integrated circuit devices of respective embodiments of the present application will be explained.

As shown in FIGS. 30 and 31 (FIG. 6), after patterning the gate electrode 16 using the hard mask film 44 for gate processing, as shown in FIG. 32, an insulating film 24 for a side wall, which is constituted of a side wall under layer silicon oxide film 24c (for example, around 10 nm in thickness), a side wall silicon nitride film 24b (for example, around 60 nm in thickness) and a side wall upper layer silicon oxide film 24a (for example, TEOS silicon oxide film, for example, around 170 nm in thickness) etc., is formed over approximately the entire surface of the device main surface la of the wafer 1 by CVD etc.

Next, as shown in FIG. 33, the side wall upper layer silicon oxide film 24a is subjected to an anisotropic etching treatment by anisotropic dry etching.

Next, as shown in FIG. 34, the side wall silicon nitride film 24b is subjected to an isotropic etching treatment by isotropic dry etching or wet etching.

Next, as shown in FIGS. 35 and 36 (corresponding to the state in FIG. 11), the side wall under layer silicon oxide film 24c is subjected to an isotropic etching treatment by isotropic dry etching or wet etching. On this occasion, a part of the side wall under layer silicon oxide film 24c may be left as a silicon oxide film for ion implantation to be carried out later.

7. Explanation of the structure etc. of the CMOS configuration in the semiconductor integrated circuit device in the second embodiment of the present application (mainly FIG. 37)

The example of this Section corresponds to the example on Section 4. However, in the example of Section 4, the high breakdown voltage N-channel type MISFET Qnh and the high breakdown voltage P-channel type MISFET Qph have ripple parts (wave undulations) 20n and 20p that are different in the pitch each other, but have ripple bottom parts (bottom parts or trench parts of the wave undulation) 30n and 30p that are approximately the same in depth each other. In contrast, in the example in this Section, inversely, the high breakdown voltage N-channel type MISFET Qnh and the high breakdown voltage P-channel type MISFET Qph have ripple parts (wave undulations) 20n and 20p that are approximately the same in the pitch (for example, around 1.4 μm, that is, the width of both bottom part and highland are around 0.7 μm), but are different in the depth of ripple bottom parts (bottom parts or trench parts of the wave undulation) 30n and 30p (see Section 8). That is, the P-channel and the N-channel have approximately the same wavelength but different wave heights each other. Except for the parts explained here, the explanation in this Section is approximately the same as the explanation in Section 4.

FIG. 37 is a local top face view of a semiconductor substrate showing the device structure of CMOS configuration in the semiconductor integrated circuit device of a second embodiment of the present application. On the basis of this, the structure etc. of the CMOS configuration in the semiconductor integrated circuit device in the second embodiment of the present application will be explained.

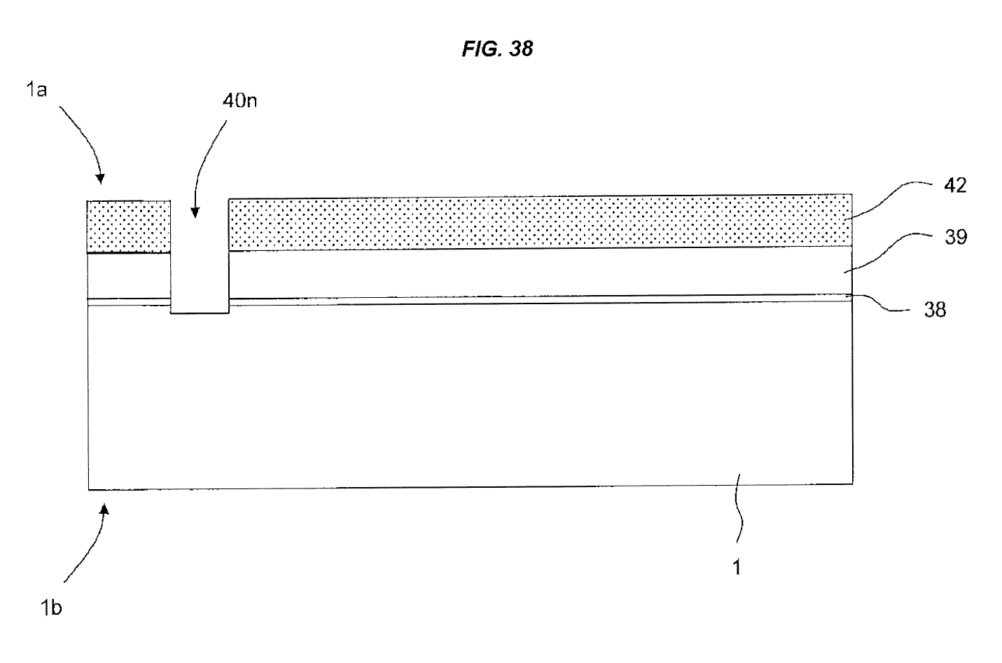

As shown in FIG. 37, the high breakdown voltage N-channel type MISFET Qnh and the high breakdown voltage P-channel type MISFET Qph have ripple parts (wave undulations) 20n and 20p that are approximately the same in the pitch (wavelength). On the other hand, as will be described in Section 8, a trench 40n for n-channel side ripple is shallower as compared with the element isolation trench 37, the trench 40p for p-channel side ripple, the trench 34 of recess channel part, the trench 35 of recess drain part etc. (see FIGS. 38, 39 and 42). That is, the depth of the trench 40n for n-channel side ripple is set to be, for example, around 50% to 80% of that of other trenches.

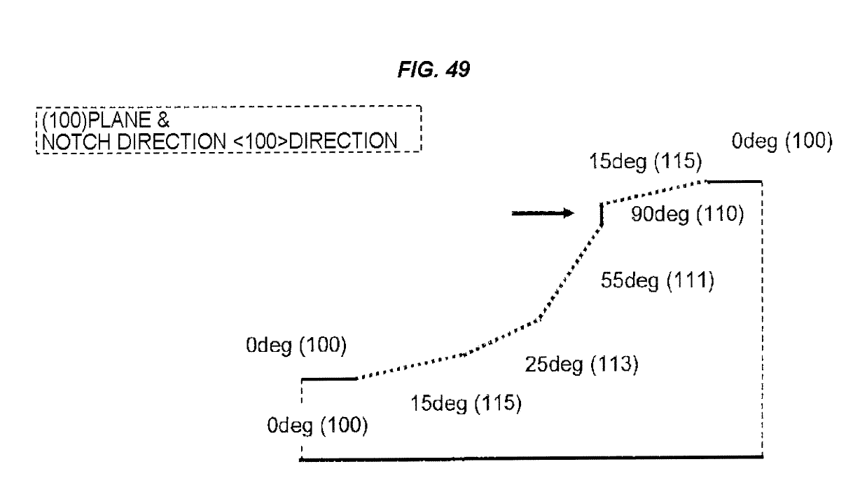

As described above, in the example, in the high breakdown voltage N-channel type MISFET Qnh, the exposure of (110) plane that decreases the mobility in N-channel type MISFETs is avoided by setting the depth of the trench 40n to be shallow (see FIG. 49).

8. Explanation of the relevant part process flow in the manufacturing method of a semiconductor integrated circuit device of the second embodiment of the present application (mainly FIGS. 38 to 42, and FIG. 51)

The content of this Section is approximately the same as the content in Section 5, except for parts described below. That is, approximately, only processes in FIGS. 19 and 24 (the ripple trench of N-channel and the ripple trench of P-channel are formed by different processes) are different. That is, the process of forming various trenches is divided into two stages.

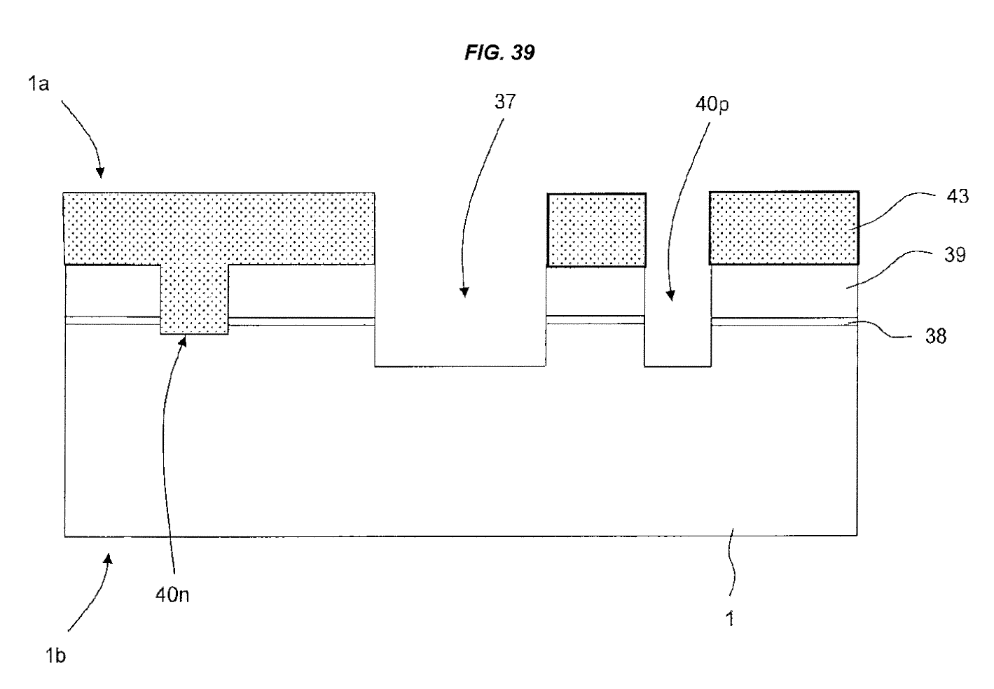

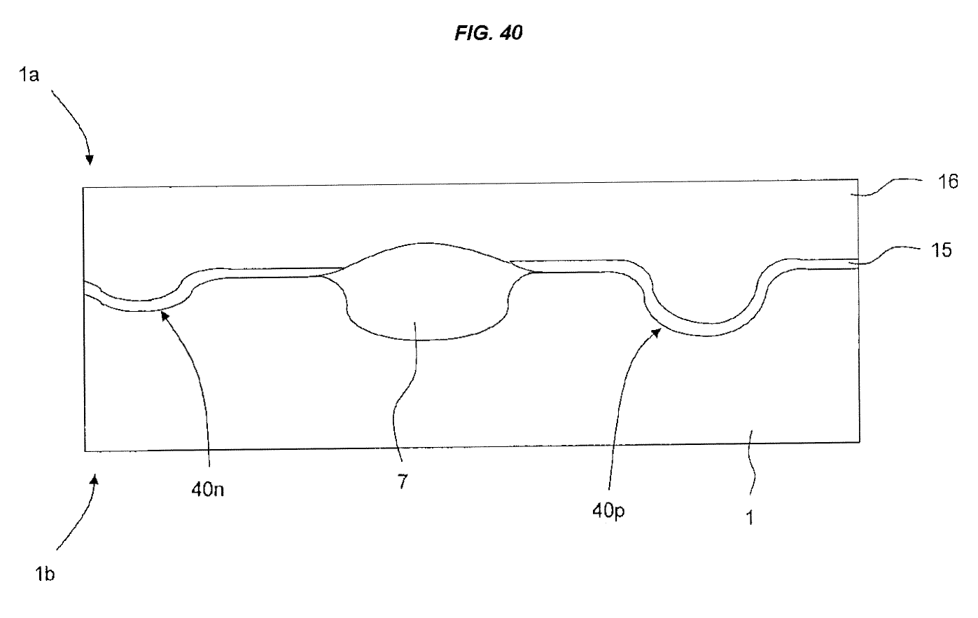

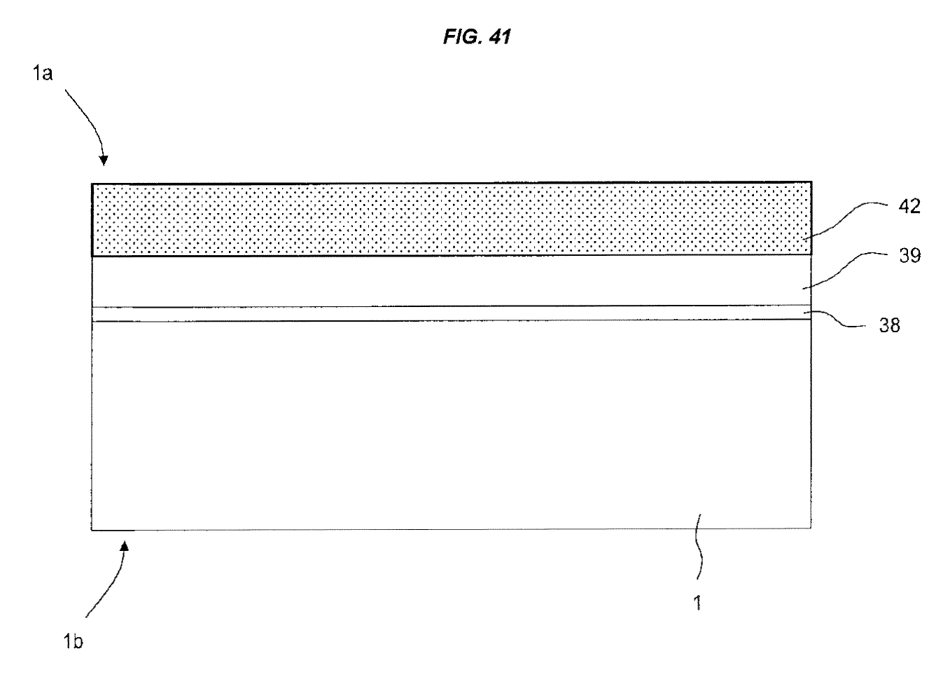

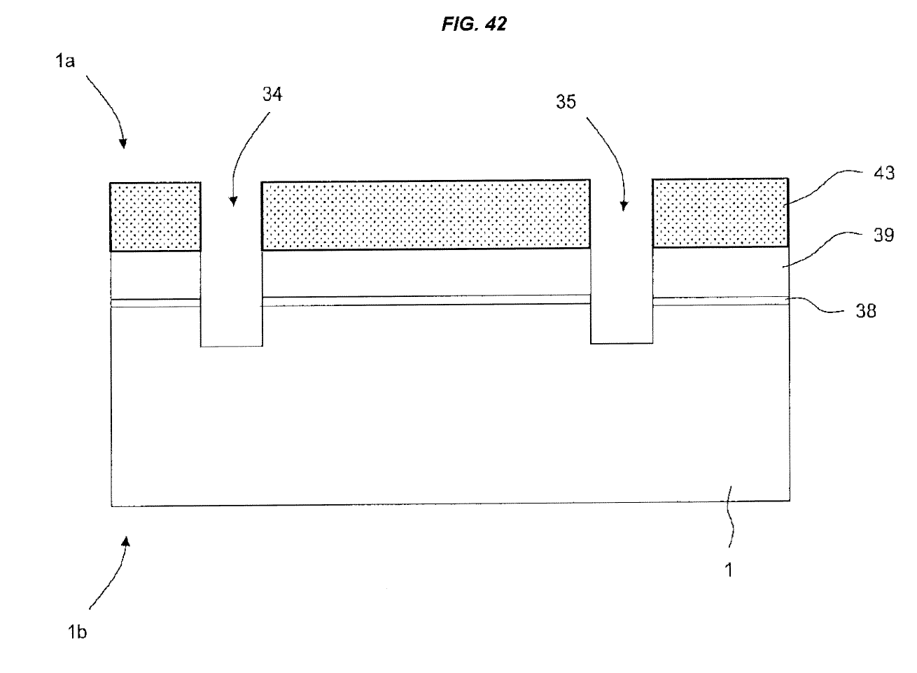

FIG. 38 is a local cross-sectional view of a device explaining a relevant part process flow in the C-C′ cross-section in FIG. 37 (process for forming a trench for an n-channel side ripple). FIG. 39 is a local cross-sectional view of a device explaining a relevant part process flow in the C-C′ cross-section in FIG. 37 (process for forming a trench for a p-channel side ripple). FIG. 40 is a local cross-sectional view of a device explaining a relevant part process flow in the C-C′ cross-section in FIG. 37 (process of flattening the upper face of the gate polysilicon film). FIG. 41 is a local cross-sectional view of a device explaining a relevant part process flow in the D-D′ cross-section in FIG. 37 (process of forming the trench for the ripple on an n-channel side before the LOCOS oxidation). FIG. 42 is a local cross-sectional view of a device explaining a relevant part process flow in the D-D′ cross-section in FIG. 37 (process of forming a trench in a recess channel part and a recess drain part before the LOCOS oxidation). FIG. 51 is a cross-sectional view of a device of parts corresponding to the ripple trench, various types of recess trenches, the element isolation trench, etc. formed in FIGS. 39 and 41, etc. for explaining the recession treatment of the insulating film for LOCOS oxidation. On the basis of these, the relevant part process flow in the manufacturing method of a semiconductor integrated circuit device of the second embodiment of the present application will be explained.

As shown in FIGS. 38 and 41, over approximately the entire surface of the device surface la of the wafer 1 in the state of FIG. 2, the silicon oxide-based insulating film (specifically, a silicon oxide film or a silicon oxynitride film) is formed, and, over approximately the entire surface thereof, the silicon nitride-based insulating film 39 (specifically, a silicon nitride film) is formed to thereby form an insulating film for LOCOS oxidation. An example of preferable thickness range of the silicon oxide-based insulating film 38 is around 5 nm to 50 nm, and that of the silicon nitride-based insulating film 39 is around 50 nm to 200 nm.

Subsequently, over approximately the entire surface of the insulating film for LOCOS oxidation, a resist film 42 for processing the trench for n-channel side ripple is coated, and the resist film 42 is patterned by ordinary lithography. Subsequently, by anisotropic dry etching, the relatively shallow trench 40n for n-channel side ripple is formed. After that, the resist film 42 for processing the trench for n-channel side ripple that has become unnecessary is removed entirely.

Next, as shown in FIGS. 39 and 42, over approximately the entire surface of the insulating film for LOCOS oxidation, a resist film 43 for processing the trench for p-channel side ripple etc. is coated, and the resist film 43 is patterned by ordinary lithography. Subsequently, by anisotropic dry etching, a relatively deep (deeper than the trench 40n for n-channel side ripple) trench 40p for p-channel side ripple, element isolation trench 37, trench 34 of recess channel part, trench 35 of recess drain part etc. are formed. After that, the resist film 43 that has become unnecessary is removed entirely.

As the result of such process, as shown in FIG. 40 (corresponding to FIG. 23), the trench for n-channel side ripple becomes somewhat shallower than the trench 40p for p-channel side ripple.

9. Explanation of the crystal plane orientation of a silicon single crystal etc. common to semiconductor integrated circuit devices of respective embodiments of the present application (mainly FIGS. 43 to 50)

In this Section, there are explained a favorable crystal orientation of a wafer for use in the semiconductor device and the manufacturing method of semiconductor device explained in above Sections (individually, a silicon single crystal is taken as an example for explanation), and the channel alignment thereof with high breakdown voltage MISFETs (Qnh, Qph) and low breakdown voltage MISFETs (Qnc, Qpc). Here, an example is explained where a notch is adopted as the part of displaying wafer orientation, but, needless to say, one using an orientation flat etc. is acceptable.

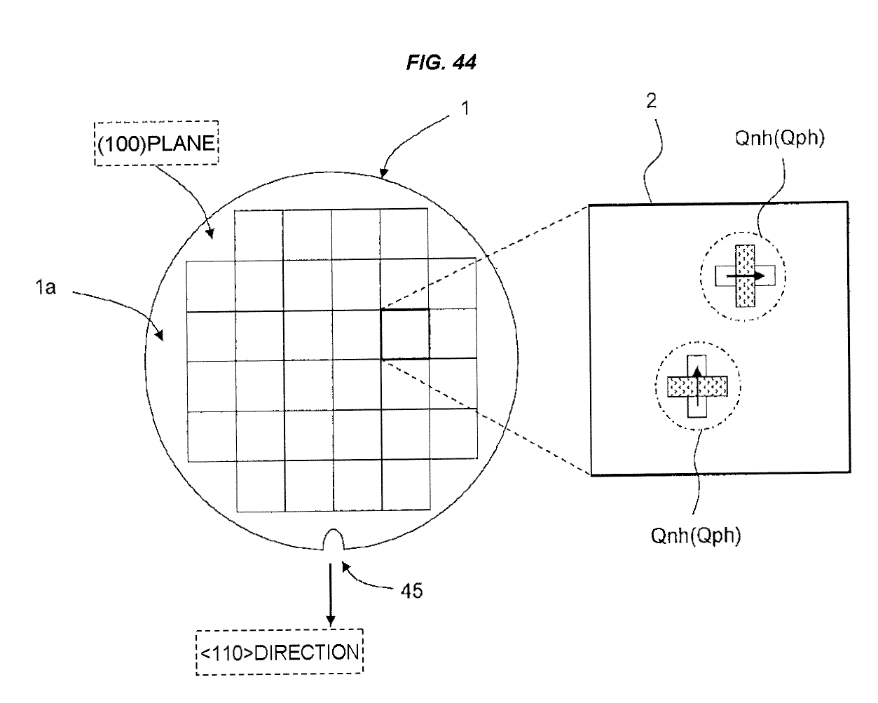

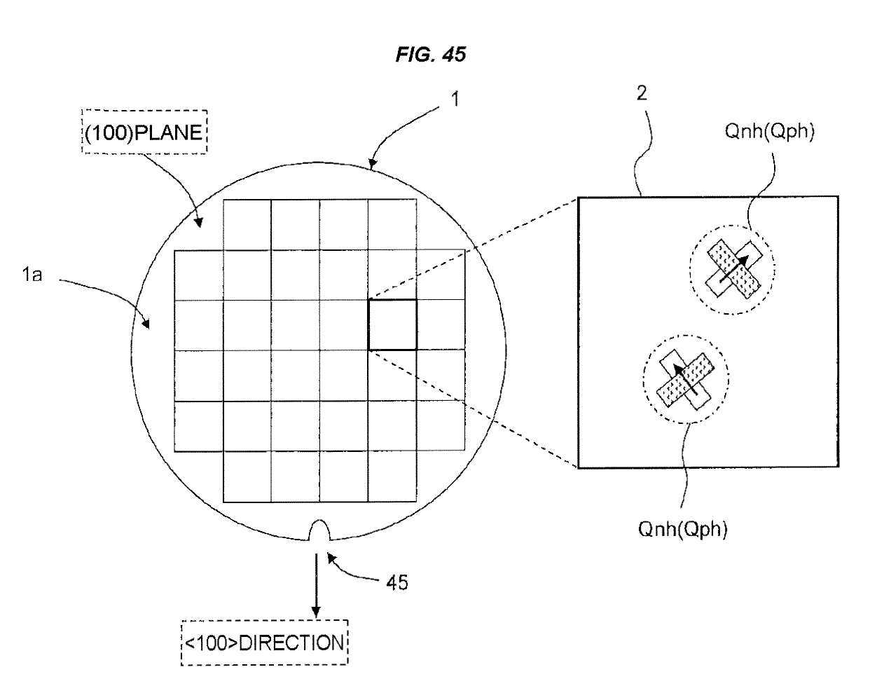

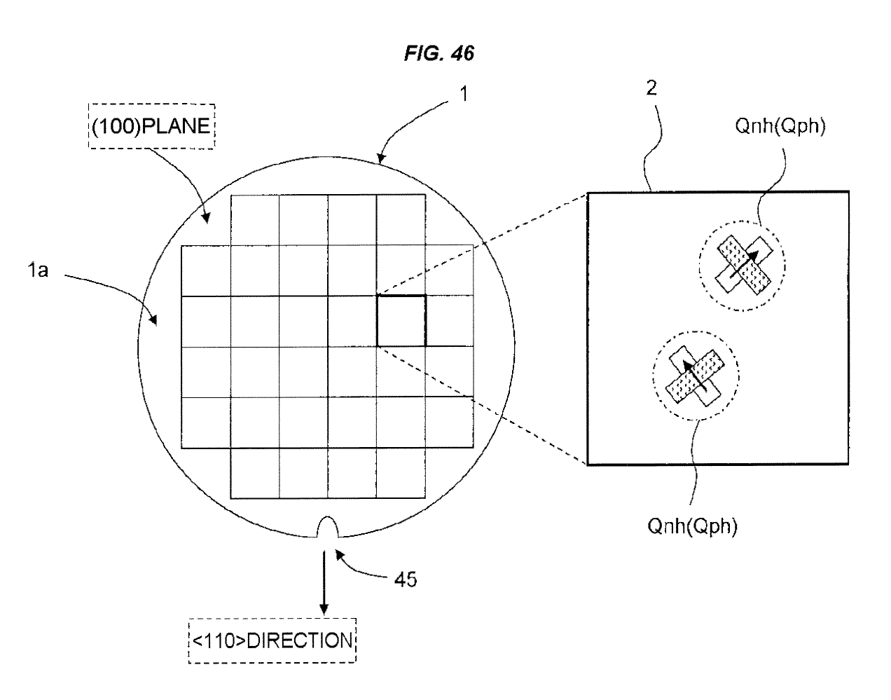

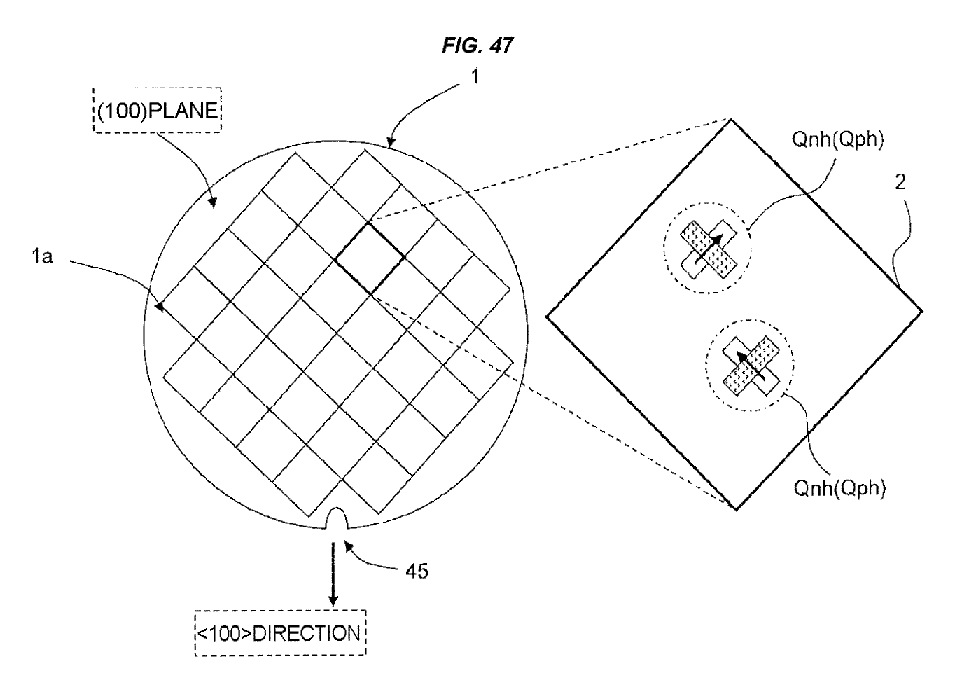

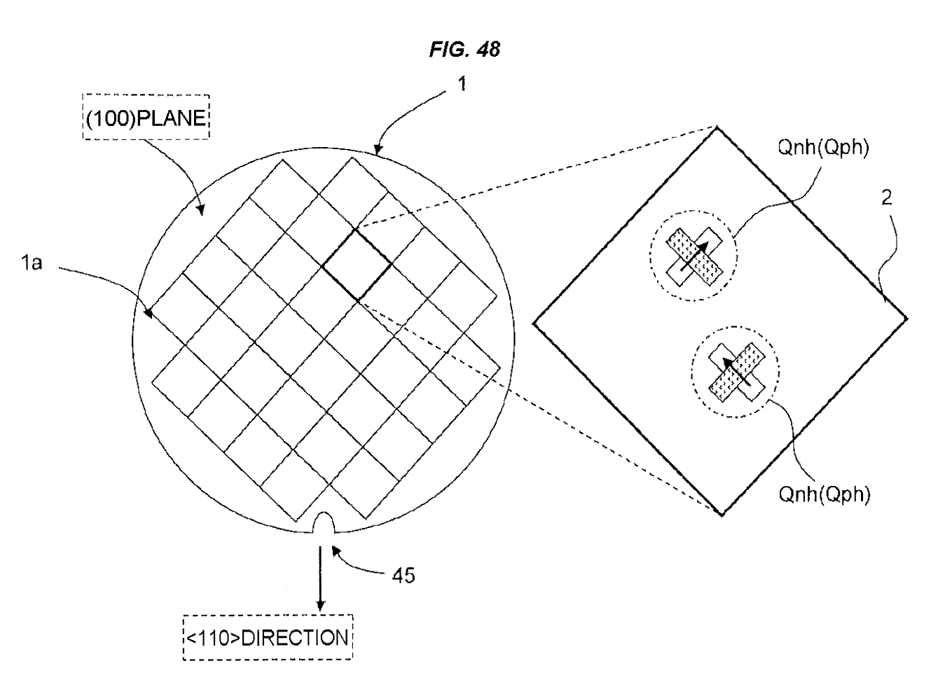

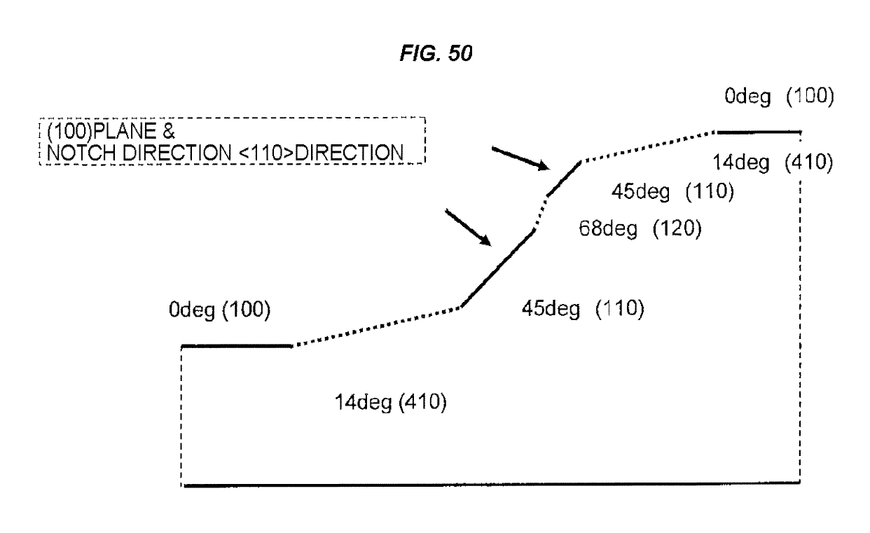

FIG. 43 is a schematic view of the wafer top face explaining the alignment of the crystal plane orientation of a silicon single crystal and the channel direction (the channel length direction) of the high breakdown voltage MISFET common to semiconductor integrated circuit devices of respective embodiments of the present application (alignment example 1). FIG. 44 is a schematic view of the wafer top face explaining the alignment of the crystal plane orientation of a silicon single crystal and the channel direction (the channel length direction) of the high breakdown voltage MISFET common to semiconductor integrated circuit devices of respective embodiments of the present application (alignment example 2). FIG. 45 is a schematic view of the wafer top face explaining the alignment of the crystal plane orientation of a silicon single crystal and the channel direction (the channel length direction) of the high breakdown voltage MISFET common to the semiconductor integrated circuit devices of respective embodiments of the present application (alignment example 3). FIG. 46 is a schematic view of the wafer top face explaining the alignment of the crystal plane orientation of a silicon single crystal and the channel direction (the channel length direction) of the high breakdown voltage MISFET common to the semiconductor integrated circuit devices of respective embodiments of the present application (alignment example 4). FIG. 47 is a schematic view of the wafer top face explaining the alignment of the crystal plane orientation of a silicon single crystal and the channel direction (the channel length direction) of the high breakdown voltage MISFET common to the semiconductor integrated circuit devices of respective embodiments of the present application (alignment example 5). FIG. 48 is a schematic view of the wafer top face explaining the alignment of the crystal plane orientation of a silicon single crystal and the channel direction (the channel length direction) of the high breakdown voltage MISFET common to the semiconductor integrated circuit devices of respective embodiments of the present application (alignment example 6). FIG. 49 is an explanatory view showing a trench cross-section for showing the degree of easiness of the appearance of (110) plane in the case of the alignment in FIG. 43. FIG. 50 is an explanatory view showing a trench cross-section for showing the degree of easiness of the appearance of (110) plane in the case of the alignment in FIG. 44. On the basis of these, the crystal plane orientation of a silicon single crystal etc. common to the semiconductor integrated circuit devices of respective embodiments of the present application will be explained.

As shown in FIGS. 49 and 50, in the case where the device main surface 1a (first main surface) of the wafer 1 (silicon single crystal) has a plane orientation of (100), from the comparison of the case where the crystal orientation in a notch direction 45 is <100> (which is referred to as “0° wafer”) and the case where the crystal orientation in the notch direction 45 is <110> (which is referred to as “45° wafer”) about the easiness of giving the (110) plane, it is known that the 45° wafer gives the (110) plane easier. As compared with the (100) plane, the (110) plane has an enhanced hole mobility, but a decreased electron mobility. Accordingly, in the high breakdown voltage MISFETs (Qnh, Qph) accompanied with various trenches, the 45° wafer is advantageous for the P-channel type MISFET (Qph), but is disadvantageous for the N-channel type MISFET (Qnh). Accordingly, for a chip 2 in which the P-channel type MISFET (Qph) occupies a large area, the 45° wafer is advantageous, and, for a chip 2 in which the N-channel type MISFET (Qnh) occupies a large area or the N-channel type MISFET (Qnh) and the P-channel type MISFET (Qph) occupy comparable areas, the 0° wafer is advantageous.

In specific explanation of this, for a chip 2 in which the N-channel type MISFET (Qnh) occupies a large area, or the N-channel type MISFET (Qnh) and the P-channel type MISFET (Qph) occupy comparable areas, as shown in FIG. 43, the 0° wafer 1 is used while adopting a chip alignment, in which respective main axes (axes parallel to respective edges) of the chip are parallel to respective <100> directions (including directions equivalent thereto, hereinafter the same), and laying out the high breakdown voltage MISFETs (Qnh, Qph) so that the gate length direction 46 becomes parallel to respective <100> directions. Such alignment makes it possible to bring out to the maximum the performance of the CMOS or CMIS circuit as a whole. Meanwhile, usually, the same layout of the low breakdown voltage MISFETs (Qnc, Qpc) as these is effective for using effectively such infrastructures as various design support tools, mask manufacturing and wafer treating devices, and inspection devices.

Next, for a chip 2 in which the P-channel type MISFET (Qph) occupies a large area, as shown in FIG. 44, the 45° wafer 1 is used while adopting a chip alignment, in which respective main axes (axes parallel to respective edges) of the chip are parallel to respective <100> directions (including directions equivalent thereto, hereinafter the same), and laying out the high breakdown voltage MISFETs (Qnh, Qph) so that the gate length direction 46 becomes parallel to respective <100> directions. Such alignment makes it possible to bring out to the maximum the performance of the CMOS or CMIS circuit as a whole. Meanwhile, usually, the same layout of the low breakdown voltage MISFETs (Qnc, Qpc) as these is effective for using effectively various design support tools, mask manufacturing and wafer treating devices, and inspection devices.

Next, the layout shown in FIG. 47 realizes the same matter as in FIG. 45 by the 0° wafer 1, which is obtained by rotating entirely the chip alignment by 45°. The system may bring about a certain kind of problem in using effectively such infrastructures as various design support tools, mask manufacturing and wafer treating devices, and inspection devices, but has such merit that an identical wafer is usable with another product (when the other product uses a 0° wafer) (the standardization of the wafer specification). Meanwhile, in this case, the same layout of the low breakdown voltage MISFETs (Qnc, Qpc) as these is, usually, effective from the viewpoint of the occupation area etc., although not limited to it.

The same state as in FIG. 47 can also be realized in the way as in FIG. 45. That is, using the 0° wafer 1, the gate length direction of the high breakdown voltage MISFETs (Qnh, Qph) is rotated in 45° while leaving the chip alignment as it is (as that shown in FIG. 44). Meanwhile, in this case, usually, it is effective to leave the chip alignment as it is (as that shown in FIG. 44) in the gate length direction of the low breakdown voltage MISFETs (Qnc, Qpc) from the standpoint of using effectively such infrastructures as various design support tools, mask manufacturing and wafer treating devices, and inspection devices. The layout may be accompanied by some disadvantage from the viewpoint of occupation area etc.

Next, the layout shown in FIG. 48 realizes the same matter as in FIG. 44 by the 45° wafer 1, which is obtained by rotating entirely the chip alignment by 45°. The system may bring about a certain kind of problem in using effectively such infrastructures as various design support tools, mask manufacturing and wafer treating devices, and inspection devices, but has such merit that an identical wafer is usable with another product (when the other product uses a 45° wafer) (the standardization of the wafer specification). Meanwhile, in this case, the same layout of the low breakdown voltage MISFETs (Qnc, Qpc) as these is, usually, effective from the viewpoint of the occupation area etc., although not limited to it.

The same state as in FIG. 48 can also be realized in the way as in FIG. 46. That is, using the 45° wafer 1, the gate length direction of the high breakdown voltage MISFETs (Qnh, Qph) is rotated in 45° while leaving the chip alignment as it is (as that shown in FIG. 45). Meanwhile, in this case, usually, it is effective to leave the chip alignment as it is (as that shown in FIG. 45) in the gate length direction of the low breakdown voltage MISFETs (Qnc, Qpc) from the standpoint of using effectively such infrastructures as various design support tools, mask manufacturing and wafer treating devices, and inspection devices. The layout may be accompanied by some disadvantage from the viewpoint of occupation area etc.

10. Summary

Until now, the invention achieved by the inventor has specifically been explained on the basis of embodiments, but the invention is not limited to it but, needless to say, it can be changed variously in a range that is not deviated from the gist thereof.

For example, in respective embodiments, a semiconductor device or a semiconductor integrated circuit device using a silicon-based single crystal wafer was mainly taken as an example and specifically explained, but the invention of the application is not limited thereto, but, needless to say, is applicable to semiconductor devices or semiconductor integrated circuit devices using an epitaxial wafer, an SOI wafer, or the like.

In respective embodiments, as the element isolation structure, mainly one using a LOCOS isolation structure is specifically explained, but, needless to say, the invention of the application is not limited thereto and it can be applied to one using the STI (Shallow Trench Isolation).

Moreover, in respective embodiments, as the wiring structure, mainly one using an aluminum-based ordinary wiring is specifically explained, but, needless to say, the invention of the application can also be applied to one using an embedded wiring structure such as a cupper damascene wiring.

Furthermore, in respective embodiments, a gate first process was taken as an example and was specifically explained, but, needless to say, the invention of the application is not limited thereto, but is applicable to a gate last process etc.

Meanwhile, in respective embodiments, examples that are not accompanied with silicidation of the source, drain, gate electrode etc. are explained, but, needless to say, the invention is not limited thereto and is applicable to one utilizing a process of forming a silicide layer of a metal such as titanium, cobalt or nickel over the surface of the source, drain, gate electrode, etc.

What is claimed is:

1. A semiconductor integrated circuit device, comprising:
(a) a semiconductor substrate having a first and a second main surface; (b) a first N-channel type MISFET and a first P-channel type MISFET provided over the first main surface of the semiconductor substrate; (c) a first wave undulation provided over the surface of a first channel region of the first N-channel type MISFET so as to lie along the channel width direction; and (d) a second wave undulation provided over the surface of a second channel region of the first P-channel type MISFET so as to lie along the channel width direction, wherein the pitch of the first wave undulation is shorter than that of the second wave undulation.

2. The semiconductor integrated circuit device according to claim 1, wherein the first wave undulation is provided extending from a first source region to a first drain region of the first N-channel type MISFET, and the second wave undulation is provided extending from a second source region to a second drain region of the first P-channel type MISFET.

3. The semiconductor integrated circuit device according to claim 2, wherein the first wave undulation is provided extending between respective contact regions of the first source region and the first drain region of the first N-channel type MISFET, and the second wave undulation is provided extending between respective contact regions of the second source region and the second drain region of the first P-channel type MISFET.

4. The semiconductor integrated circuit device according to claim 3, wherein the respective contacts of the respective contact regions are provided for both top and bottom parts of the respective first wave undulation and the second wave undulation.

5. The semiconductor integrated circuit device according to claim 4, wherein a first in-channel recess region is provided in the surface in an approximately central part of the first channel region so as to lie along the channel width direction, and a second in-channel recess region is provided in the surface in an approximately central part of the second channel region so as to lie along the channel width direction.

6. The semiconductor integrated circuit device according to claim 5, further comprising: (e) a second N-channel type MISFET and a second P-channel type MISFET provided over the first main surface of the semiconductor substrate, wherein the source-drain breakdown voltage of the first N-channel type MISFET is higher than that of the second N-channel type MISFET, and the source-drain breakdown voltage of the first P-channel type MISFET is higher than that of the second P-channel type MISFET.

7. The semiconductor integrated circuit device according to claim 6, wherein the first drain region includes: (x1) a low concentration N-type drain region; (x2) a high concentration N-type drain region that is provided in a surface region in the low concentration N-type drain region and has a higher impurity concentration than the low concentration N-type drain region; and (x3) a recess region in the N-type drain provided in the surface of the low concentration N-type drain region without the high concentration N-type drain region so as to lie along the channel width direction, and, furthermore, the second drain region includes: (y1) a low concentration P-type drain region; (y2) a high concentration P-type drain region that is provided in a surface region in the low concentration P-type drain region and has a higher impurity concentration than the low concentration P-type drain region; and (y3) a recess region in the P-type drain provided in the surface of the low concentration P-type drain region without the high concentration P-type drain region so as to lie along the channel width direction.

8. The semiconductor integrated circuit device according to claim 7, wherein the wave height of the second wave undulation and that of the first wave undulation are approximately equal to each other.

9. The semiconductor integrated circuit device according to claim 8, wherein the semiconductor chip is a silicon-based semiconductor, the first main surface has a crystal plane of approximately (100) plane, and respective channel length directions of the first N-channel type MISFET and the first P-channel type MISFET lie approximately along the crystal orientation <100>.

10. The semiconductor integrated circuit device according to claim 8, wherein the semiconductor chip is a silicon-based semiconductor, the first main surface has a crystal plane of approximately (100) plane, and respective channel length directions of the first N-channel type MISFET and the first P-channel type MISFET lie approximately along the crystal orientation <110>.

11. A semiconductor integrated circuit device, comprising: (a) a semiconductor substrate having a first and a second main surface; (b) a first N-channel type MISFET and a first P-channel type MISFET provided over the first main surface of the semiconductor substrate; (c) a first wave undulation provided over the surface of a first channel region of the first N-channel type MISFET so as to lie along a channel width direction; and (d) a second wave undulation provided over the surface of a second channel region of the first P-channel type MISFET so as to lie along the channel width direction, wherein the wave height of the first wave undulation is higher than that of the second wave undulation.

12. The semiconductor integrated circuit device according to claim 11, wherein the semiconductor chip is a silicon-based semiconductor, the first main surface has a crystal plane of approximately (100) plane, and respective channel length directions of the first N-channel type MISFET and the first P-channel type MISFET lie approximately along the crystal orientation <100>.

13. The semiconductor integrated circuit device according to claim 11, wherein the semiconductor chip is a silicon-based semiconductor, the first main surface has a crystal plane of approximately (100) plane, and respective channel length directions of the first N-channel type MISFET and the first P-channel type MISFET lie approximately along the crystal orientation <110>.

14. A semiconductor integrated circuit device, comprising: (a) a semiconductor substrate having a first and a second main surface; (b) a first N-channel type MISFET and a first P-channel type MISFET that are provided over the first main surface of the semiconductor substrate in close vicinity to each other and constitute a first pair of CMISFETs; (c) a first wave undulation provided over the surface of a first channel region of the first N-channel type MISFET so as to lie along a channel width direction; and (d) a second wave undulation provided over the surface of a second channel region of the first P-channel type MISFET so as to lie along the channel width direction.

15. The semiconductor integrated circuit device according to claim 14, further comprising: (e) a second N-channel type MISFET and a second P-channel type MISFET provided over the first main surface of the semiconductor substrate, wherein the source-drain breakdown voltages of the first N-channel type MISFET and the first P-channel type MISFET are higher than those of the second N-channel type MISFET and the second P-channel type MISFET.

16. A manufacturing method of a semiconductor integrated circuit device, the semiconductor integrated circuit device comprising: (a) a semiconductor substrate having a first and a second main surface; (b) a first N-channel type MISFET and a first P-channel type MISFET provided over the first main surface of the semiconductor substrate; (c) a first wave undulation provided over the surface of a first channel region of the first N-channel type MISFET so as to lie along a channel width direction; (d) a second wave undulation provided over the surface of a second channel region of the first P-channel type MISFET so as to lie along the channel width direction; (e) a first in-channel recess region provided in the surface in an approximately central part of the first channel region so as to lie along the channel width direction; and (f) a second in-channel recess region provided in the surface in an approximately central part of the second channel region so as to lie along the channel width direction, wherein the manufacturing method of a semiconductor integrated circuit device comprises the step of: (p1) forming the first wave undulation and the first in-channel recess region approximately at the same time.

17. The manufacturing method of a semiconductor integrated circuit device according to claim 16, the semiconductor integrated circuit device comprising: (g) a LOCOS element isolation insulating film element-isolating the first N-channel type MISFET and the first P-channel type MISFET over the first main surface of the semiconductor substrate, wherein the manufacturing method of a semiconductor integrated circuit device further comprises the step of: (p2) after the step (p1), carrying out, approximately at the same time, oxidation for chamfering respective corner parts of the first wave undulation, the second wave undulation, the first in-channel recess region, and the second in-channel recess region, and oxidation for forming the LOCOS element isolation insulating film.

18. The manufacturing method of a semiconductor integrated circuit device according to claim 17, wherein the pitch of the first wave undulation is shorter than that of the second wave undulation.

19. The manufacturing method of a semiconductor integrated circuit device according to claim 18, wherein the first wave undulation and the second wave undulation are formed by different processes.

20. The manufacturing method of a semiconductor integrated circuit device according to claim 19, further comprising the step of: (p3) after the step (p2), removing an oxide film formed in the oxidation for the chamfering in a state where the LOCOS element isolation insulating film is covered with an etching-resistant material.
